(19) United States
(12) Patent Application Publication
(10) Pub. No.: US 2009/0065896 A1
(43) Pub. Date: Mar. 12, 2009

(54) CAPACITOR HAVING Ru ELECTRODE AND TiO2 DIELECTRIC LAYER FOR SEMICONDUCTOR DEVICE AND METHOD OF FABRICATING THE SAME

(75) Inventor: Cheol Seong Hwang, Seongnam-si (KR)

Correspondence Address: OCCHIUTI ROHLICEK & TSAO, LLP, 10 FAWCETT STREET, CAMBRIDGE, MA, 02138, US

(73) Assignee: Seoul National University Industry Foundation, Seoul (KR)

(21) Appl. No.: 11/851,766

(22) Filed: Sep. 7, 2007

(51) Int. Cl. H01L 29/92; H01L 21/425

(52) U.S. Cl. 257/532; 438/394; 257/E29.342; 257/E21.008

(57) ABSTRACT

Provided are a capacitor of a semiconductor device using a TiO₂ dielectric layer and a method of fabricating the capacitor. The capacitor includes a Ru bottom electrode formed on a semiconductor substrate, an rutile-structures RuO₂ pretreated layer which is formed by oxidizing the Ru bottom electrode, a TiO₂ dielectric layer which has a rutile crystal structure corresponding to the rutile crystal structure of the RuO₂ pretreated layer and is doped with an impurity, and a top electrode formed on the TiO₂ dielectric layer. The method includes forming a Ru bottom electrode on a semiconductor substrate, forming a rutile-structured RuO₂ pretreated layer by oxidizing a surface of the Ru bottom electrode, forming a TiO₂ dielectric layer to have a rutile crystal structure corresponding to the rutile crystal structure of the RuO₂ pretreated layer on the a RuO₂ pretreated layer and doping the TiO₂ dielectric layer with an impurity, and forming a top electrode on the TiO₂ dielectric layer.

### BACKGROUND OF THE INVENTION

1. Field of the Invention

The present invention relates to a capacitor of a semiconductor device and a method of fabricating the same, and more particularly, to a capacitor of a semiconductor device having a substantially increased capacitance density and a method of fabricating the same.

2. Description of the Related Art

Dynamic random access memory (DRAM) which is a semiconductor device consists of one transistor and one capacitor. In order to improve capacitance of such a semiconductor device including capacitors, it is important to increase capacitance of the capacitors. Capacitance of capacitors can be increased by forming a bottom electrode as a three-dimensional structure, by increasing the height of a bottom electrode, or by reducing the thickness of a dielectric layer. However, there is a limit to secure stable and large capacitance in narrow spaces. As such, high-k dielectric layers are more demanded. Examples of a high-k material include Ta₂O₅, TiO₂, Al₂O₃, Y₂O₃, ZrO₂, HfO₂, BaTiO₃, SrTiO₃, (Ba,Sr)TiO₃ etc.

High-k dielectric layers, however, easily react with poly-silicon, which is conventionally used to form an electrode of a capacitor, to thus form a low-k layer at the interface between the dielectric layer and the electrode. Thus, the low-k layer makes it difficult to secure larger capacitance. In order to solve this problem, it is required that a bottom electrode, or both a bottom electrode and a top electrode be formed of materials which are more difficult to be oxidized than poly-silicon or materials of which oxide is still electrically conducting. The materials which are more difficult to be oxidized than poly-silicon can be a novel metal, such as Pt; materials of which oxide is still electrically conducting are Ru, or Ir; a heat-resistance metal, such as tungsten (W); or a heat-resistance metal nitrate, such as tungsten nitrate (WN) or titanium nitrate (TiN), tantalum nitride (TaN), or ternary nitrides, such as TiSiN, TaSiN, TiAlN, and TaAlN.

Meanwhile, among high-k dielectrics, ternary dielectrics, such as SrTiO₃ (STO) and (Ba,Sr)TiO₃ (BSTO), have approximately as a few ten times large dielectric constant as binary dielectrics, such as HfO₂, ZrO₂, Ta₂O₅, and TiO₂. However, ternary dielectrics are difficult to be deposited due to their material structures, and their stoichiometries are difficult to be properly controlled. In addition, ternary dielectrics require a post heat treatment over a temperature of 700° C. and thus, an electrode material can be deformed. Accordingly, ternary dielectrics are still difficult to be practically used in a method of fabricating a semiconductor device.

Among binary dielectrics, a Ta₂O₅ film which is formed on a Ru electrode through a metal-organic chemical vapor deposition (MOCVD) has received attentions due to its dielectric constant of over 60. However, the Ta₂O₅ film also requires a post heat treatment temperature over 600° C., and at such a high temperature, the deformation of the Ru electrode is very severe.

Accordingly, there is a need to develop a dielectric layer of a capacitor formed of materials which has a simpler structure than ternary dielectrics, has large dielectric constant, and can be processed at low temperature.

### SUMMARY OF THE INVENTION

The present invention provides a capacitor of a semiconductor device including a dielectric layer formed of materials having a simple structure and large dielectric constant.

The present invention also provides a method of fabricating a capacitor of a semiconductor device, in which a dielectric layer formed of materials having a simple structure and a dielectric constant is formed at low temperature.

According to an aspect of the present invention, there is provided a capacitor of a semiconductor device. The capacitor includes a Ru bottom electrode formed on a semiconductor substrate; a rutile-structured RuO₂ pretreated layer which is formed by oxidizing the Ru bottom electrode; a TiO₂ dielectric layer which has a rutile crystal structure corresponding to the rutile-structured RuO₂ pretreated layer and is doped with an impurity; and a top electrode formed on the TiO₂ dielectric layer.

The thickness of the RuO₂ pretreated layer can be 5 nm or less. The impurity includes at least one substance selected from Al and Hf, and the concentration of the impurity can be in the range from 0.1 at % to 20 at %. The top electrode can be formed of a novel metal, heat-resistance metal, heat-resistance metal nitrate, or conductive oxide. The novel metal can be Ru, Pt, or Ir; the heat-resistance metal nitrate can be TiN, TaN, WN, TiSiN, TaSiN, TiAlN, and TaAlN; and the conductive oxide can be RuO₂, IrO₂, or SrRuO₃.

According to another aspect of the present invention, there is provided a method of fabricating a capacitor of a semiconductor device. The method includes: forming a Ru bottom electrode on a semiconductor substrate; forming a rutile-structured RuO₂ pretreated layer by oxidizing a surface of the Ru bottom electrode; forming a TiO₂ dielectric layer to have a rutile crystal structure corresponding to the rutile crystal structure of the rutile-structured RuO₂ pretreated layer on the RuO₂ pretreated layer, and doping the TiO₂ dielectric layer with an impurity; and forming a top electrode on the TiO₂ dielectric layer.

Herein, the RuO₂ pretreated layer can be formed and then the TiO₂ dielectric layer begins to be formed, or the RuO₂ pretreated layer can be formed in the process of forming the TiO₂ dielectric layer. The Ru bottom electrode can be formed through atomic layer deposition (ALD) with or without plasma or chemical vapor deposition (CVD). The RuO₂ pretreated layer can be formed by performing a heat treatment on the Ru bottom electrode using an ozone gas before the TiO₂ dielectric layer begins to be formed. Alternatively, the RuO₂ pretreated layer can also be formed using an ozone gas acting as an oxidant in the process of forming the TiO₂ dielectric layer.

In the method, the process for forming RuO₂ pretreated layer and the process for forming the TiO₂ dielectric layer are performed in-situ, wherein the semiconductor substrate can be loaded into a reaction chamber; an ozone gas can be supplied to the reaction chamber to oxidize the surface of the Ru bottom electrode so as to form the RuO₂ pretreated layer; and the TiO₂ dielectric layer can be formed using an atomic layer deposition method in which TiO₂ deposition cycle can be repeated several times, wherein the TiO₂ deposition cycle includes: supplying a Ti precursor to the reaction chamber, purging the Ti precursor out of the reaction chamber, supplying an oxidant to the reaction chamber, and purging the oxidant out of the reaction chamber. The oxidant can be ozone gas, water vapor, or oxygen plasma.

In the method, the process for forming the RuO₂ pretreated layer and the process for forming the TiO₂ dielectric layer are formed in-situ, wherein the semiconductor substrate can be loaded to a reaction chamber; and the TiO₂ dielectric layer can be formed using an atomic layer deposition method that a TiO₂ deposition cycle can be repeated several times, and at the same time, the surface of the Ru bottom electrode can be oxidized using the ozone gas or oxygen plasma with a proper density so as to form the RuO₂ pretreated layer, wherein the TiO₂ deposition cycle includes: supplying a Ti precursor to the reaction chamber, purging the Ti precursor in the reaction chamber, supplying an oxidant to the reaction chamber, and purging the oxidant in the reaction chamber.

The method, after the TiO₂ dielectric layer is formed, can further includes performing a post heat treatment, and the TiO₂ dielectric layer can be formed at 400° C. or less and the post heat treatment can be performed at 500° C. or less.

The at least one substance selected from Al and Hf can be doped with a concentration from 0.1 at % to 20 at %. To dope with the at least one substance selected from Al and Hf, an impurity source including the at least one substance selected from Al and Hf can be supplied in a vapor phase in the process of forming the TiO₂ dielectric layer. In this process, the impurity source can be supplied together with, or separately from the Ti precursor.

To dope with the at least one substance selected from Al and Hf, an impurity source layer including the at least one substance selected from Al and Hf can be deposited on the TiO₂ dielectric layer, and then the least one substance selected from Al and Hf can be diffused into the TiO₂ dielectric layer.

### BRIEF DESCRIPTION OF THE DRAWINGS

The above and other features and advantages of the present invention will become more apparent by describing in detail exemplary embodiments thereof with reference to the attached drawings in which:

FIG. 1 is a sectional view illustrating a capacitor of a semiconductor device according to first embodiment of the present invention;

FIGS. 2 through 8 are sectional views illustrating a method of fabricating a capacitor of a semiconductor device according to second embodiment of the present invention;

FIG. 9 and FIG. 10 are flow charts illustrating a process of forming a TiO₂ dielectric layer in the method of fabricating a capacitor of a semiconductor device according to second embodiment of the present invention;

FIGS. 11 and 12 are flow charts illustrating a process of forming a TiO₂ dielectric layer in the method of fabricating a capacitor of a semiconductor device according to third embodiment of the present invention;

FIG. 13 is a graphical view of an equivalent oxide thickness with respect to a physical thickness of a TiO₂ dielectric layer in which Al is not doped;

FIG. 14 illustrates X-ray diffraction (XRD) analysis data of a TiO₂ dielectric layer formed according to third embodiment of the present invention;

FIG. 15 illustrates X-ray photoelectron spectroscopy (XPS) spectrum data of the interface between a Ru electrode and a TiO₂ dielectric layer when the TiO₂ dielectric layer is formed according to third embodiment of the present invention;

FIG. 16 is a graphical view of a leakage current with respect to voltage (J-V) of an Al-doped TiO₂ dielectric layer and an un-doped TiO₂ dielectric layer;

FIG. 17 is a graphical view of an equivalent oxide thickness with respect to a physical thickness of an Al-doped TiO₂ dielectric layer doped with Al having an optimal doping concentration;

FIG. 18 is a graphical view of a leakage current with respect to voltage (J-V) of an Al-doped TiO₂ dielectric layer doped with Al having an optimal doping concentration;

FIG. 19 is a graphical view of a leakage current with respect to an equivalent oxide thickness of an Al-doped TiO₂ dielectric layer and an un-doped TiO₂ dielectric layer;

FIG. 20 is a graphical view of a leakage current with respect to an equivalent oxide thickness of an Al-doped TiO₂ dielectric layer and an Hf-doped TiO₂ dielectric layer;

FIG. 21 is a graphical view of a leakage current with respect to voltage (J-V) of an Al-doped TiO₂ dielectric layer, an Hf-doped TiO₂ dielectric layer, and an impurity-undoped TiO₂ dielectric layer, at the same equivalent oxide thickness of 6 Å;

FIG. 22 illustrates the equivalent oxide thickness and dielectric constant of an Al-doped TiO₂ dielectric layer in an as-deposited state, an Al-doped TiO₂ dielectric layer after being subjected to a post heat treatment process, and an Al-doped TiO₂ dielectric layer after being treated with O₃;

FIG. 23 is a graphical view of a leakage current with respect to voltage (J-V) of an Al-doped TiO₂ dielectric layer in a as-deposited state, an Al-doped TiO₂ dielectric layer after being subjected to a post heat treatment process, and an Al-doped TiO₂ dielectric layer after being treated with O₃;

FIG. 24 illustrates glancing angle X-ray diffraction (GAXRD) analysis data of a TiO₂ dielectric layer formed on a RuO₂ pretreated layer which have been formed by pre-treating with ozone gas according to second embodiment of the present invention, and a comparative sample in which a TiO₂ dielectric layer is directly formed on a Ru bottom electrode without a pre-treatment process using an ozone gas;

FIG. 25 is a graphical view of an equivalent oxide thickness with respect to a physical thickness of a TiO₂ dielectric layer formed using various deposition methods;

FIG. 26 is a schematic sectional view of a sample used in an experimental example according to the present invention;

FIG. 27 is a graphical view of capacitance according to the distance of a hole in which a un-doped TiO₂ dielectric layer is deposited, at various hole sizes; and

FIG. 28 is a graphical view of capacitance according to the distance of a hole in which an Al-doped TiO₂ dielectric layer is deposited, at various hole sizes.

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity. Like reference numerals in the drawings denote like elements, and thus their description will be omitted.

### FIRST EMBODIMENT

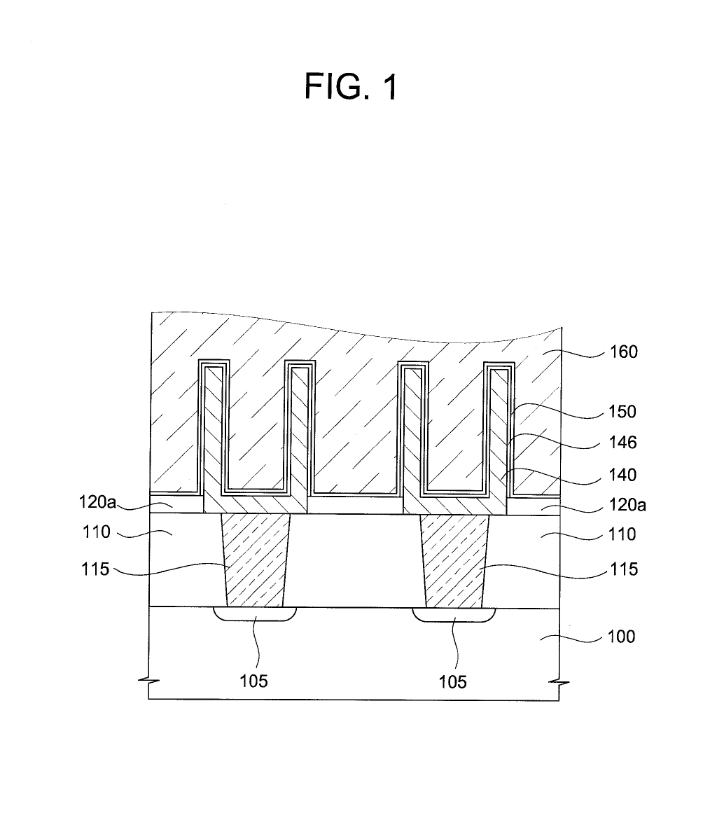

FIG. 1 is a sectional view illustrating a capacitor of a semiconductor device according to first embodiment of the present invention.

Referring to FIG. 1, a capacitor of a semiconductor device according to the present invention includes a Ru bottom electrode 140a deposited on a semiconductor substrate 100, a rutile-structured RuO₂ pretreated layer 146 which is formed by oxidizing the Ru bottom electrodes 140a, a TiO₂ dielectric layer 150 which is formed to have a rutile crystal structure which corresponds to the crystal structure of the RuO₂ pretreated layer 146, and is doped with an impurity, and a top electrode 160 deposited on the TiO₂ dielectric layer 150. The top electrode 160 can be a novel metal, a heat-resistance metal, a heat-resistance metal nitrate, or a conductive oxide. Specifically, the novel metal can be Ru, Pt, or Ir; the heat-resistance metal nitrate can be TiN, TaN, WN, TiSiN, TaSiN, TiAlN, and TaAlN; and the conductive oxide can be RuO₂, IrO₂, or SrRuO₃.

The semiconductor substrate 100 can include a transistor (not shown) having an impurity region 105 as a source and a drain, and a bottom insulating layer 110 including a contact plug 115 can be formed on the semiconductor substrate 100. An etch stopper pattern 120a can be formed on the bottom insulating layer 110. In FIG. 1, some structures formed on the semiconductor substrate 100 are not illustrated to easily describe the present invention.

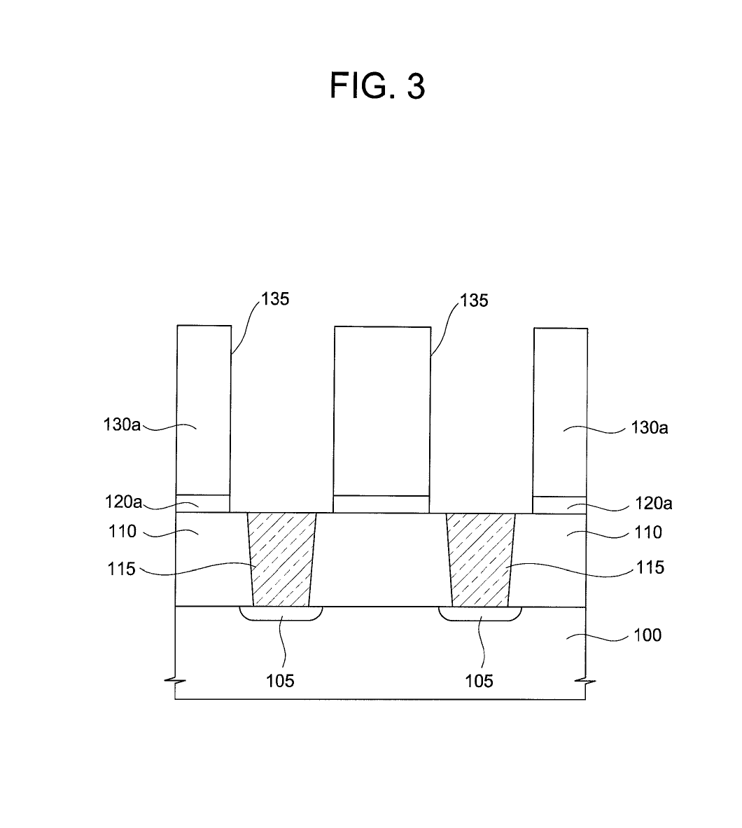

A capacitor illustrated in FIG. 1 is a cylinder-like capacitor in which upper, outer, and inner surfaces of the Ru bottom electrode 140a are used as a surface area of a capacitor. However, the present invention is not limited thereto. For example, the capacitor according to the present invention can be a concave-like capacitor in which only upper and inner surfaces of the Ru bottom electrode 140a are used as a surface area of a capacitor. Or, the capacitor according to the present invention can be a stack-like capacitor. In the case of concave-like and stack-like capacitors, a mold oxide pattern (refer to 130a in FIGS. 3 through 5) can be interposed between adjacent two Ru bottom electrodes 140a.

In FIG. 1, the capacitor is located above a bit line in a DRAM, which is like a capacitor over bit line (COB). However, the present invention is not limited thereto. For example, like a capacitor under bit line (CUB), the capacitor can be located under a bit line, or like a trench-like capacitor, the capacitor can be formed in a semiconductor substrate.

According to the present invention, the thickness of the RuO₂ pretreated layer 146 may be 5 nm or less. The TiO₂ dielectric layer 150 has large dielectric constant due to its rutile crystal structure. In addition, the TiO₂ dielectric layer 150 can be more easily formed to have the rutile crystal structure even at low temperature than when the RuO₂ pretreated layer 146 is not formed, since the TiO₂ dielectric layer 150 is formed to have a structure which corresponds to the rutile crystal structure of the RuO₂ pretreated layer 146. An impurity which is doped in the TiO₂ dielectric layer 150 may be at least one substance selected from Al and Hf. The concentration of the impurity may be in the range from 0.1 to 20 at %, specifically, from 1 to 15 at %. Through the doping with the impurity, a decrease in dielectric constant of the TiO₂ dielectric layer 150 can be minimized, and leakage current properties can be hugely improved. Thus, as illustrated in experimental examples, a dielectric layer having an equivalent oxide thickness of 0.5 nm or less can be achieved. When the concentration of at least one substance selected from Al and Hf which is to be doped in the TiO₂ dielectric layer 150 is less than 0.1 at %, no doping effect occurs. On the other hand, when the concentration of at least one substance selected from Al and Hf which is to be doped on the TiO₂ dielectric layer 150 is higher than 20 at %, the decrease of the dielectric constant of the TiO₂ dielectric layer 150 is dominant over improvement in a leakage current properties.

As described above, a capacitor of a semiconductor device according to the present invention includes a TiO₂ dielectric layer having high dielectric constant which is formed of a binary dielectric layer having a simpler structure than ternary dielectric layer, in which the TiO₂ dielectric layer is doped with an impurity to minimize a decrease in dielectric constant and to substantially improve a leakage current properties.

### SECOND EMBODIMENT

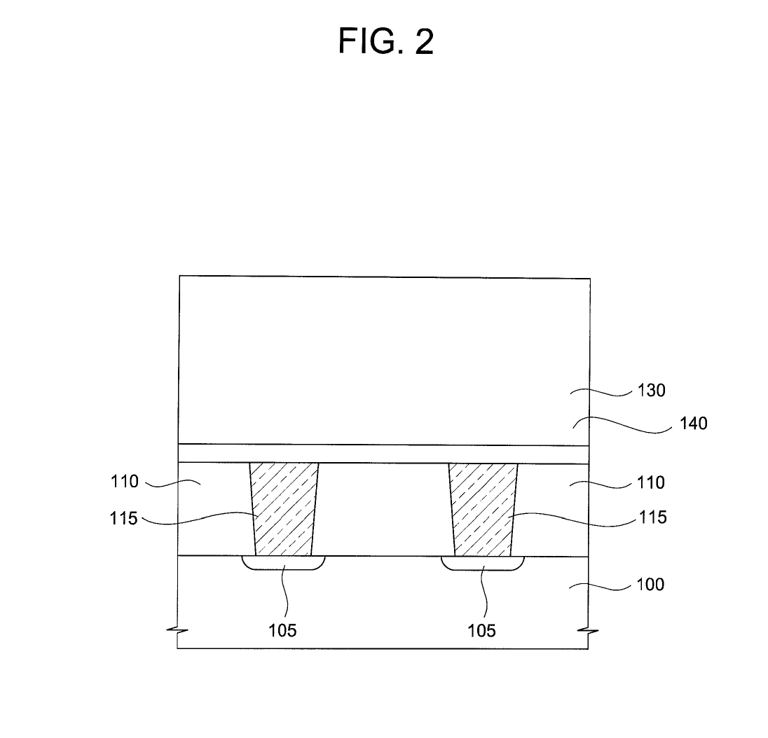

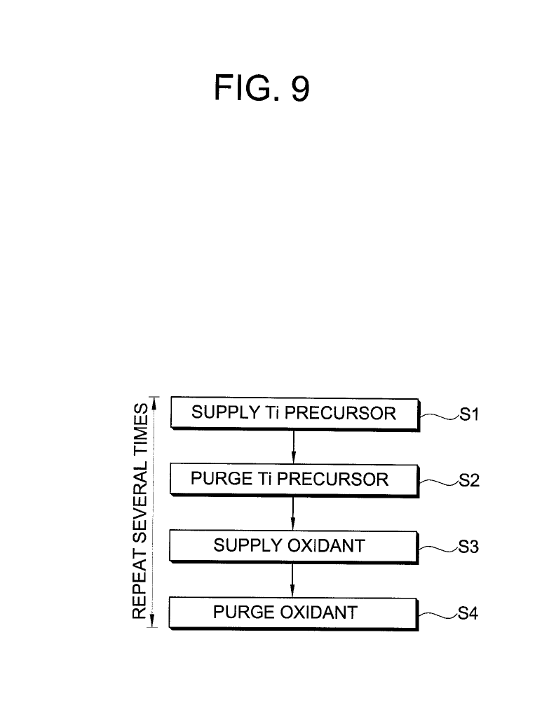

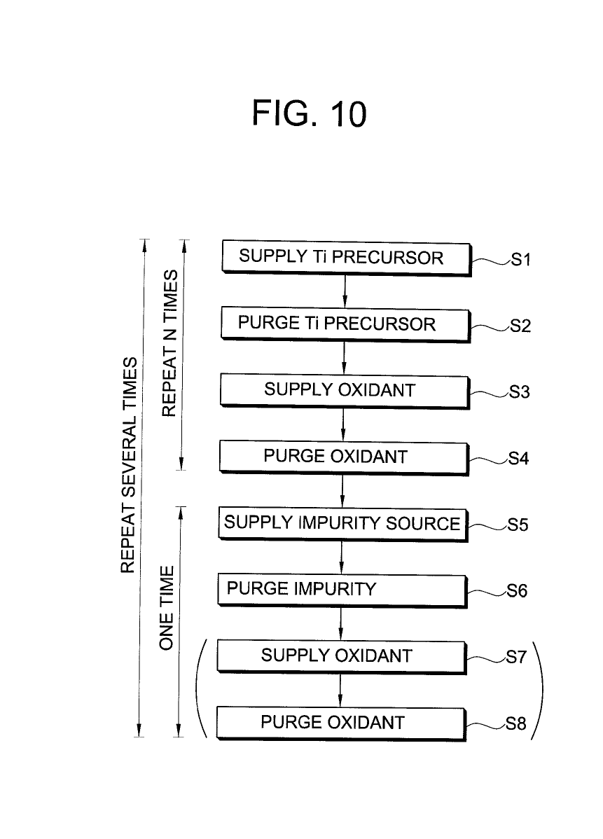

FIGS. 2 through 8 are sectional views illustrating a method of fabricating a capacitor of a semiconductor device according to second embodiment of the present invention. FIG. 9 and FIG. 10 are flow charts illustrating a process of forming a TiO₂ dielectric layer in the method of fabricating a capacitor of a semiconductor device according to the second embodiment of the present invention.

Referring to FIG. 2, an active region is defined in a semiconductor substrate 100 using a device isolation process, such as a local oxidation of silicon (LOCOS) process or a shallow trench isolation (STI) process, and then a transistor structure having an impurity region 105 as source and drain is formed in the active region. The semiconductor substrate 100 used for a DRAM can be a silicon wafer in conventional cases, but is not limited thereto. For example, the semiconductor substrate 100 can be a silicon on insulator (SOI) or a silicon on sapphire (SOS).

A bottom insulating layer 110 is formed on the transistor structure, and then a plurality of contact plugs 115 which pass through the bottom insulating layer 110 to contact the impurity region 105 of the semiconductor substrate 100 are formed in the bottom insulating layer 110. An etch stopper 120 is formed using, for example, silicon nitrate on the contact plugs 115 and the bottom insulating layer 110, and then, boron phosphorus silicate glass (BPSG), phosphorus silicate glass (PSG), plasma enhanced (PE)—tetra ethyl ortho silicate (TEOS) or high density plasma (HDP)—oxide can be deposited on the etch stopper 120 to form a mold oxide layer 130.

Referring to FIG. 3, the mold oxide layer 130 is etched to form a mold oxide layer pattern 130a until a top surface of the etch stopper 120 is exposed. In this process, the etch stopper 120 protects the bottom insulating layer 110 from being etched. Subsequently, an etching process is performed to remove only the exposed portion of the etch stopper 120 to form a hole 135 exposing the contact plugs 115 and portions of the bottom insulating layer 110 surrounding the contact plugs 115s. The etch stopper pattern 120a remains under the mold oxide layer pattern 130a.

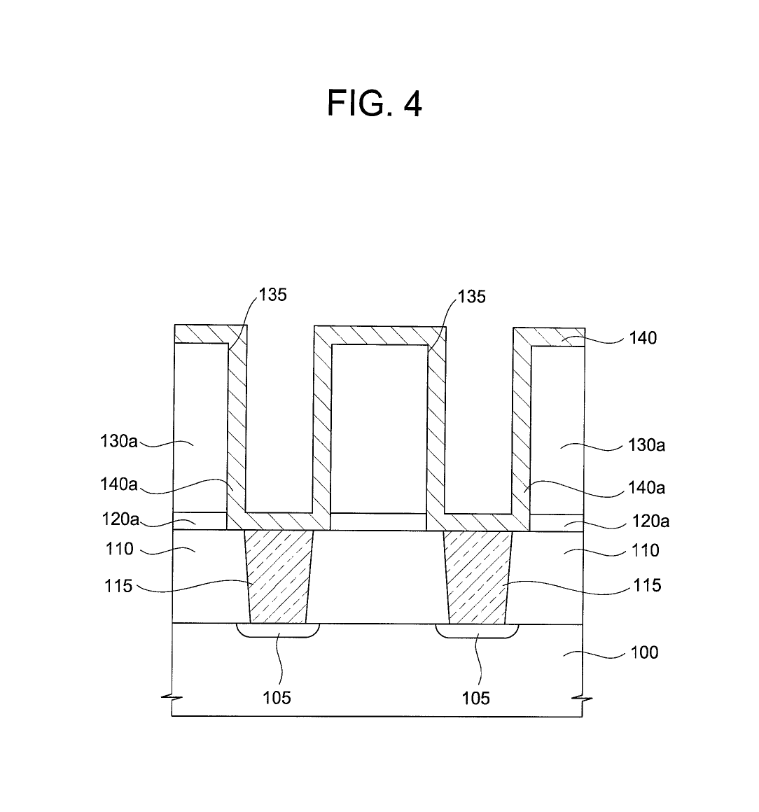

Referring to FIG. 4, a Ru layer 140 is formed with a thickness as large as not to completely fill the hole 135. The Ru layer 140 is to be a bottom electrode of a capacitor according to the present invention, and can be formed using a sputtering method. However, the Ru layer 140 can also be formed using an atomic layer deposition (ALD) method with or without plasma or a chemical vapor deposition (CVD) method.

Herein, the ALD method is kind of a chemical vapor deposition method. In the ALD method, a source gas is supplied and chemically adsorbed to a surface of a substrate, the remaining source gas which is not absorbed to the surface of a substrate is purged, and then, a material layer is formed from the adsorbed source gas. The cycle which includes supplying of a source gas and purging of the source gas can be repeated to obtain a material layer having a desired thickness. According to this method, conventionally, the thickness of the material layer can be adjusted to a unit of an atomic layer, and thus, the material layer has an excellent step coverage and the concentration of an impurity in the material layer is very low.

When the Ru layer 140 is formed using an ALD method, first, a TiO₂ layer that is a seed layer and a glue layer is formed to a thickness of 10 nm at 250° C. using Ti OC₃H_{7 4} and H₂O as a source gas, and then a Ru layer 140 can be formed at 300° C. using Ru(EtCp)₂, Ru(Cp,i-PrCp), or DER acting as a source, and O₂ and plasma activated H₂ acting as a reaction gas. A gas supply time and a gas purge time may be 0.1 seconds and 5 seconds, respectively.

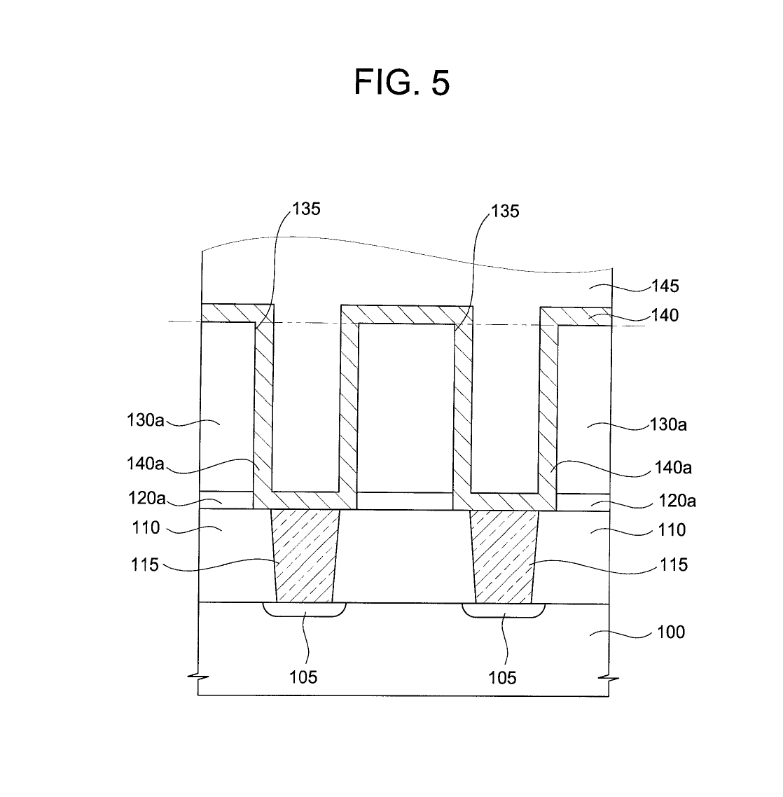

Referring to FIG. 5, a capping layer 145, such as an un-doped silicate glass (USG) layer having excellent gap filling properties, is deposited on the Ru layer 140 to fill the hole 135. Then, the capping layer 145 and the Ru layer 140 are remove using an etch back process or a chemical mechanical polishing (CMP) process until a top surface of the mold oxide layer pattern 130a is exposed, that is, a portion above the doted line illustrated in FIG. 5 is removed. As such, respectively separated bottom electrodes 140a of a capacitor are formed.

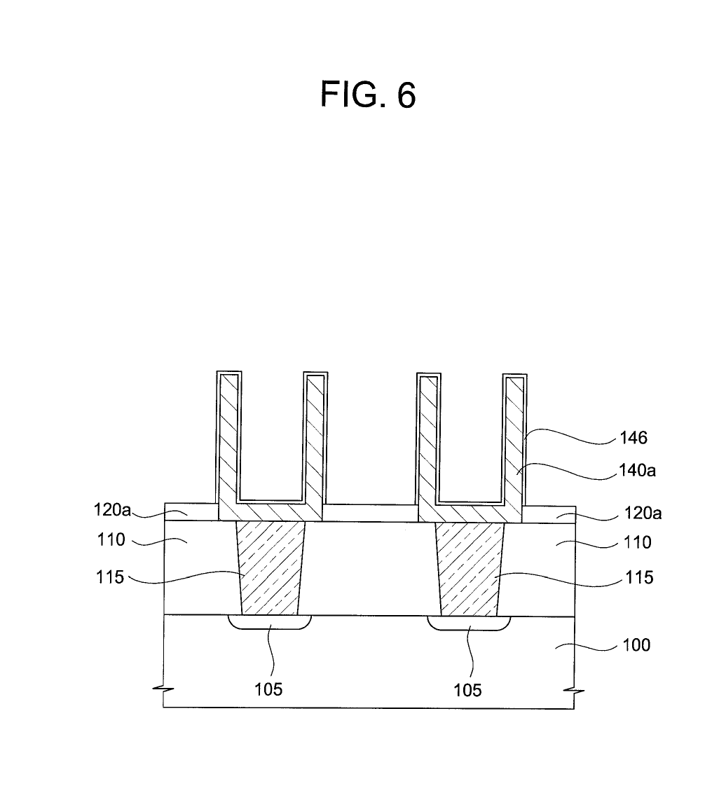

Referring to FIG. 6, the capping layer 145 and the mold oxide layer pattern 130a are removed using a wet etching process to expose the Ru bottom electrode 140a. Thus, a cylinder-like capacitor can be fabricated in which the upper, outer, and inner surfaces of the Ru bottom electrode 140a can be used as a surface area of a capacitor. When the capping layer 145 alone is removed, a concave-like capacitor can be fabricated in which upper and inner surfaces of the Ru bottom electrode 140a can be used as a surface area of a capacitor. Then, the surface of the Ru bottom electrode 140a is oxidized to form a RuO₂ pretreated layer 146 having a rutile crystal structure.

To form the RuO₂ pretreated layer 146, the Ru bottom electrode 140a is heat treated using an ozone gas or oxygen plasma at 100-400° C. For example, the heat treatment process can be performed at 250° C. for about 15 seconds. The Ru bottom electrode 140a has a hexagonal close-packed (HCP) crystal structure. However, when the surface of the Ru bottom electrode 140a is treated with ozone gas or oxygen plasma, Ru is oxidized to form an oxide layer having a rutile crystal structure. In this process, the thickness of the RuO₂ pretreated layer 146 may be 5 nm or less. The RuO₂ pretreated layer 146 formed according to the present invention acts as a seed layer of a TiO₂ dielectric layer 150 which is to be grown subsequently. Since the RuO₂ pretreated layer 146 and the TiO₂ dielectric layer 150 have almost the same lattice constants, the TiO₂ dielectric layer 150 can be epitaxially grown corresponding to the crystal structure of the RuO₂ pretreated layer 146.

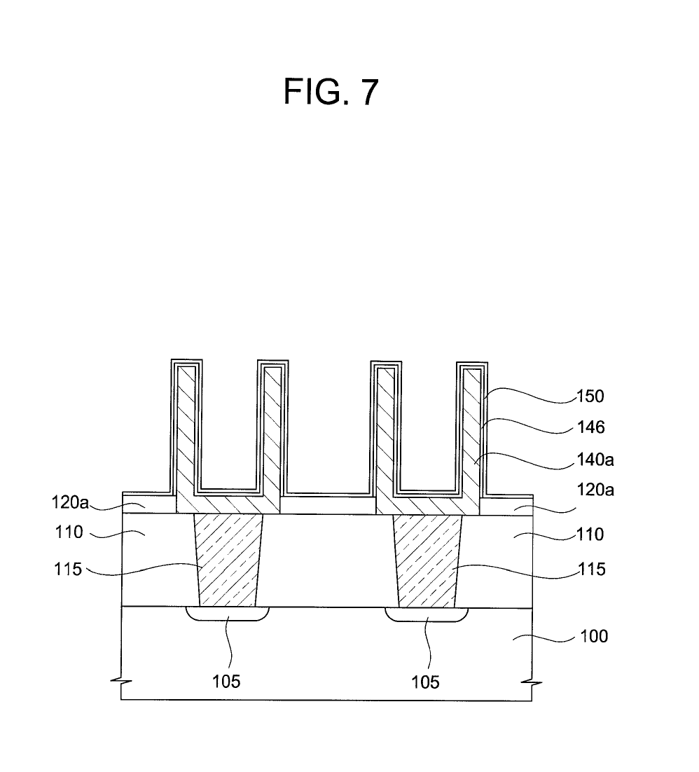

As such, according to the current embodiment, the RuO₂ pretreated layer 146 is formed and then, the TiO₂ dielectric layer 150 begins to be formed as illustrated in FIG. 7. The RuO₂ pretreated layer 146 and the TiO₂ dielectric layer 150 can be formed in-situ. That is, the semiconductor substrate 100 is loaded into a reaction chamber (not shown), and then an ozone gas or oxygen plasma is supplied to the reaction chamber to oxidize the surface of the Ru bottom electrode 140a so as to form the RuO₂ pretreated layer 146. Then, in the same reaction chamber, the TiO₂ dielectric layer 150 begins to be formed.

In general, a TiO₂ layer can have the rutile crystal structure only when TiO₂ is deposited at high temperature, for example, 700° C. or more. However, according to the present invention, since the RuO₂ pretreated layer 146 has the rutile crystal structure, the TiO₂ dielectric layer 150 growing on the RuO₂ pretreated layer 146 can be also formed to have the rutile crystal structure corresponding to the crystal structure of the RuO₂ pretreated layer 146. Accordingly, according to the current embodiment, the TiO₂ dielectric layer 150 having the rutile crystal structure can be formed at 400° C. or less.

The TiO₂ dielectric layer 150 on the Ru bottom electrode 140a having a three-dimension structure as described according to the current embodiment can be uniformly formed using a CVD method or an ALD method. A method of forming the TiO₂ dielectric layer 150 using an ALD method is illustrated in a flow chart of FIG. 9.

Referring to FIG. 9, a Ti precursor is supplied to a reaction chamber (s1). Specifically, the Ti precursor is supplied to the semiconductor substrate 100 at about 200-400° C. for about 0.1-3 seconds. Examples of an available Ti precursor include a titanium tetraisopropoxide (TTIP, Ti(O-i-C₃H₇)₄). When the Ti precursor is supplied to the semiconductor substrate 100, a portion of the Ti precursor supplied is adsorbed to the RuO₂ pretreated layer 146, and among the adsorbed Ti precursor, a chemically adsorbed Ti precursor forms a Ti metal layer that is a single atomic layer.

Then, the Ti precursor in the reaction chamber is purged (s2). In this process, a purge gas can be an inert gas, such as Ar gas or N₂ gas. The purge gas removes a portion of the Ti precursor which is not chemically adsorbed from the reaction chamber. The purge gas is supplied to the reaction chamber for about 0.1-3 seconds.

Then, an oxidant is supplied to the reaction chamber (s3). The oxidant can be ozone gas, a water vapor (H₂O), or oxygen plasma. The oxidant is supplied at about 200-400° C. for about 0.1-3 seconds. The oxidant chemically reacts with the Ti metal layer formed in (s1) to form a TiO₂ dielectric layer that is a single layer on the RuO₂ pretreated layer 146.

When the ozone gas acts as the oxidant, the amount of the ozone gas can be in the range from 100 to 500 g/m³. As the ozone gas supply time is increased, the thickness and density of the TiO₂ dielectric layer are increased, but the density of Ti in the TiO₂ dielectric layer is reduced. The TiO₂ dielectric layer shows better electrical properties, such as an equivalent oxide thickness, a leakage current density, or the like, when the ozone gas supply time is large than when the ozone gas supply time is small.

Then, the oxidant in the reaction chamber is purged (s4). A purge gas removes a portion of the oxidant which does not react from the reaction chamber. In this process, the kind of the purge gas, the purge gas supply time, and the purge gas supply temperature can be the same as in (s2). However, in some cases, the kind of the purge gas, the purge gas supply time, and the purge gas supply temperature can be different from in (s2).

A TiO₂ deposition cycle including s1 through s4 is repeated a few times to form a TiO₂ dielectric layer 150 having a rutile crystal structure to a desired thickness.

In general, when TiO₂ is deposited at high temperature, the formed TiO₂ layer has a rutile crystal structure, whereas, when TiO₂ is deposited at low temperature, the formed TiO₂ layer has an anatase crystal structure. The TiO₂ layer having the anatase crystal structure has a relative dielectric constant of about 30-40, whereas the TiO₂ layer having the rutile crystal structure has a relative dielectric constant of as high as about 90-170. Specifically, the TiO₂ layer having the rutile crystal structure that is type of a tetragonal crystal structure shows a relative dielectric constant of about 90 along an a axis that is an axis with the longer lattice parameter, but shows a relative dielectric constant of as substantially high as about 170 along a c axis that is an axis with the shorter lattice parameter. However, the TiO₂ layer having the rutile crystal structure can be formed only at high temperature, such as 700° C. or more. Thus, conventionally, when a TiO₂ layer having the rutile crystal structure is formed, a bottom structure, such as a transistor, an insulating layer, or an interconnection line, specifically, a bottom electrode formed of Ru is thermally damaged.

According to the present invention, however, the RuO₂ pretreated layer 146 has the rutile crystal structure, and thus, the TiO₂ dielectric layer 150 to be formed thereon can also have a crystal structure corresponding to the rutile crystal structure of the RuO₂ pretreated layer 146. Accordingly, the TiO₂ dielectric layer 150 having the rutile crystal structure can be formed even at low temperature, such as 400° C. or lower, specifically 200-300° C. According to the present invention, the TiO₂ dielectric layer 150 having the rutile crystal structure can be formed at low temperature, and thus a capacitor can be fabricated without deterioration of a bottom structure. In addition, large dielectric constant can be obtained.

According to the present invention, the TiO₂ dielectric layer 150 is formed and an impurity is doped in the TiO₂ dielectric layer 150. The doping with an impurity can decrease the leakage current. However, the doping with an impurity can cause a decrease in dielectric constant of the TiO₂ dielectric layer 150. Thus, the doping concentration should be adjusted to obtain an optimal effect. The inventors of the present invention found that an impurity with which the doping is performed can include at least one substance selected from Al and Hf, and the desired doping concentration is in the range from 0.1 to 20 at %. The unit ‘at %’ is based on an atomic weight of Ti. Specifically, the doping concentration can be in the range from 1 to 15 at % to improve the leakage current properties while a decrease in dielectric constant is minimized. When the concentration of at least one substance selected from Al and Hf which is to be doped in the TiO₂ dielectric layer 150 is less than 0.1 at %, no doping effect occurs. On the other hand, when the concentration of at least one substance selected from Al and Hf which is to be doped in the TiO₂ dielectric layer 150 is larger than 20 at %, the effect of the reduce in dielectric constant is stronger than that of improvement in leakage current properties.

To dope with the at least one substance selected from Al and Hf, impurity source containing the at least one substance selected from Al and Hf can be supplied in a vapor phase when the TiO₂ dielectric layer 150 is formed. Alternatively, impurity source layer containing the at least one substance selected from Al and Hf can be deposited on the TiO₂ dielectric layer 150 and then, the impurity can be diffused into the TiO₂ dielectric layer 150.

For example, to dope with Al, an Al-containing impurity source, such as TMA (trimethyl aluminum, Al(CH₃)₃), can be supplied in a vapor phase when the TiO₂ dielectric layer 150 is formed. To dope with Hf, a Hf-containing impurity source, such as TEMAHf (tetra ethyl methyl amino hafnium, Hf[N(C₂H₅)CH₃]₄), TDMAHf(tetra dimethyl amino hafnium, Hf[N(CH₃)₂]₄), TDEAHf(tetra diethyl amino hafnium, Hf[N(C₂H₅)₂]₄), HfCl₄, or NOH(Hf([N(CH₃)(C₂H₅)]₃[OC(CH₃)₃]) can be supplied in a vapor phase when the TiO₂ dielectric layer 150 is formed. To dope with Al, the TiO₂ dielectric layer 150 is formed, an Al-containing layer, such as Al₂O₃ layer, is deposited on the TiO₂ dielectric layer 150, and then, Al is diffused into the TiO₂ dielectric layer 150. To dope with Hf, the TiO₂ dielectric layer 150 is formed, an Hf-containing layer, such as HfO₂ layer, is formed on the TiO₂ dielectric layer 150 and then, Hf is diffused into the TiO₂ dielectric layer 150. The thickness of the impurity source layer may differ according to the thickness of the TiO₂ dielectric layer 150. To comply with the doping concentration described above, conventionally, the thickness of the impurity source layer can be about 0.1 nm. In case of an impurity source layer having such a thickness, the impurity can be diffused to the TiO₂ dielectric layer 150 and uniformly spread into the TiO₂ dielectric layer 150, so that no impurity source layer may remain on the TiO₂ dielectric layer 150. The impurity source layer can be deposited using an ALD method. The thickness of TiO₂ dielectric layer 150 is controlled by controlling the ALD cycle number of TiO₂ deposition. Then, one Al₂O₃ deposition cycle is performed. This sequence is repeated until the desired total thickness is achieved.

The vapor impurity source can be supplied and purged independently from the process of supplying the Ti precursor (s1) cycle, as illustrated in FIG. 10. Alternatively, the vapor impurity source can be supplied in the process of supplying the Ti precursor (s1) cycle as illustrated in FIG. 9.

Referring to FIG. 10, to dope at least one substance selected from Al and Hf on the TiO₂ dielectric layer 150, the Ti precursor is supplied to a reaction chamber (s1), the Ti precursor in the reaction chamber is purged (s2), an oxidant is supplied to the reaction chamber (s3), and then the oxidant in the reaction chamber is purged (s4). Such TiO₂ deposition cycle including (s1) through (s4) is repeated n (n≧1) times. Then, an impurity source including at least one substance selected from Al and Hf is supplied to the reaction chamber (s5), the impurity source in the reaction chamber is purged (s6), an oxidant is supplied to the reaction chamber (s7), and the oxidant in the reaction chamber is purged (s8). The doping cycle including (s5) through (s8) is performed once. The TiO₂ deposition cycle and the doping cycle described above are repeated a few times. In the doping cycle, the supplying of the oxidant to the reaction chamber (s7) and the purging of the oxidant in the reaction chamber (s8) which are in parenthesis in FIG. 10 can be omitted in some cases. In addition, the supplying of the oxidant (s3) and the purging of the oxidant (s4), which are performed directly before the doping cycle, also can be omitted in some cases. As a ratio of the repeat time of the Ti precursor to the supply time of the impurity source gets smaller, the concentration of the impurity in the TiO₂ dielectric layer 150 gets increased.

Through the doping with an impurity having an appropriate concentration, a leakage current of the TiO₂ dielectric layer 150 can be substantially improved while a decrease in dielectric constant of the TiO₂ dielectric layer 150 is minimized. Thus, as illustrated in experimental examples to be described later, a dielectric layer having an equivalent oxide thickness of 0.5 nm can be formed.

After the TiO₂ dielectric layer 150 is formed, a post heat treatment process can be further performed to improve electrical properties of the TiO₂ dielectric layer 150. For example, a resultant product including the TiO₂ dielectric layer 150 can be heat treated in a gas atmosphere containing O₂ and N₂. The post heat treatment temperature may be maintained at 500° C. or lower. Such a temperature range may not damage structural stabilities of a bottom structure and Ru bottom electrodes 140a. The post heat treatment process can be performed for 30 or less minutes.

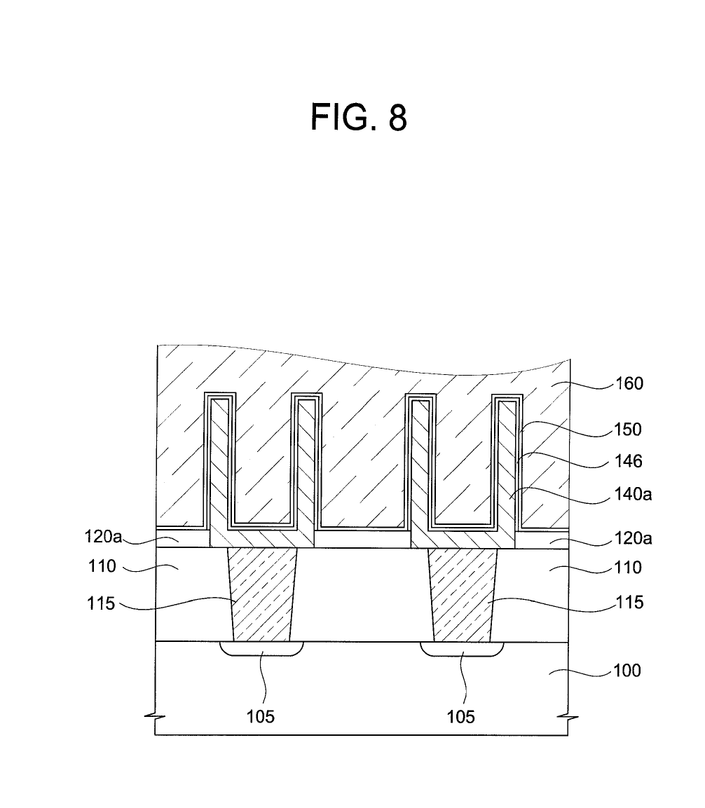

Referring to FIG. 8, a top electrode 160 is formed on the TiO₂ dielectric layer 150. The top electrode 160 can be formed of a novel metal, a heat-resistance metal, a heat-resistance metal nitrate, or conductive oxide. The novel metal can be Ru, Pt, or Ir. The heat-resistance metal nitrate can be TiN, TaN, WN, TiSiN, TaSiN, TiAlN, or TaAlN. The conductive oxide can be RuO₂, IrO₂, or SrRuO₃.

As described above, in the method of fabricating a capacitor according to the present invention, the TiO₂ dielectric layer 150 is formed to have a structure which corresponds to the crystal structure of the RuO₂ pretreated layer 146 and thus, the TiO₂ dielectric layer 150 can be formed at low temperature, such as in a temperature range from 200° C. to 300° C. In addition, the TiO₂ dielectric layer 150 can have high dielectric constant due to its rutile crystal structure. Furthermore, since the TiO₂ dielectric layer 150 is doped with an impurity, a leakage current can be substantially improved while a decrease in dielectric constant is minimized.

### THIRD EMBODIMENT

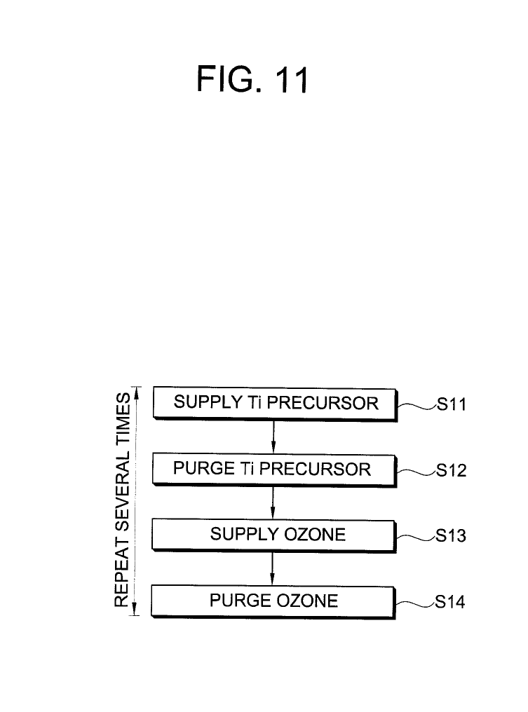

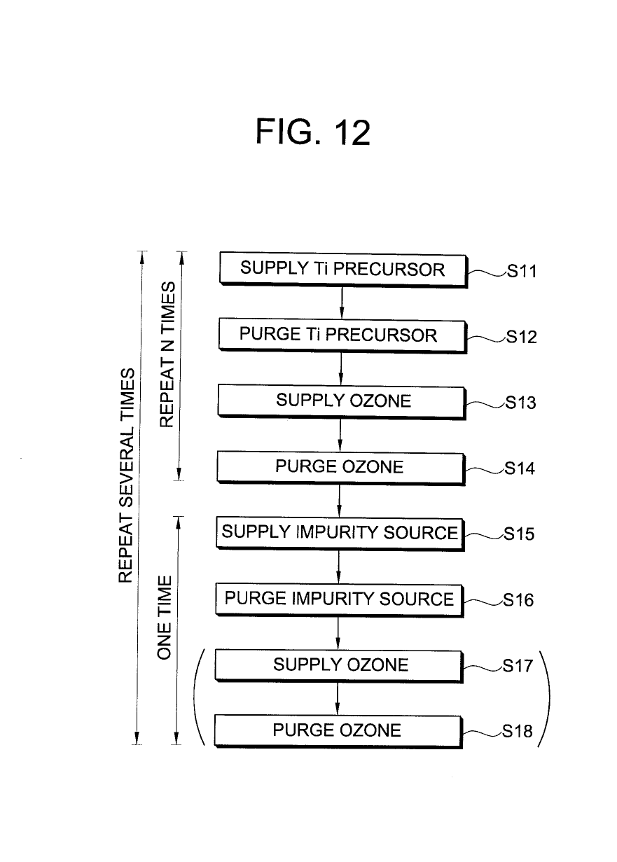

FIGS. 11 and 12 are flow charts illustrating a process of forming a TiO₂dielectric layer in a method of fabricating a capacitor of a semiconductor device according to a third embodiment of the present invention.

According to the method according to the previous embodiment, the RuO₂ pretreated layer 146 is formed and then, the TiO₂ dielectric layer 150 is formed. However, when the TiO₂ dielectric layer 150 is formed, that is, after the TiO₂ dielectric layer 150 begins to be formed and before the TiO₂ dielectric layer 150 is completely formed, the RuO₂ pretreated layer 146 can be formed. To form the RuO₂ pretreated layer 146, ozone or oxygen plasma gas can be used as an oxidant during the TiO₂ dielectric layer 150 is formed. This method described above will now be described in detail.

First, the method of fabricating a capacitor is performed up to the process which has been described with reference to FIG. 5. Then, the capping layer 145 and the mold oxide layer pattern 130a are removed using a wet etching process to expose a surface of the Ru bottom electrode 140a.

Then, the semiconductor substrate 100 is loaded to a reaction chamber, and then the TiO₂ dielectric layer 150 begins to be formed according to the flow chart illustrated in FIG. 11 or FIG. 12. The RuO₂ pretreated layer 146 can be formed using ozone gas as an oxidant when the TiO₂ dielectric layer 150 is formed.

Referring to FIG. 11, the Ti precursor is supplied to a reaction chamber (s11), the Ti precursor in the reaction chamber is purged (s12), ozone gas is supplied to the reaction chamber (s13), and then the ozone gas in the reaction chamber is purged (s14). A TiO₂ dielectric layer 150 as illustrated in FIG. 7 is formed using an ALT method that the TiO₂ deposition cycle including (s11) through (s14) is repeated a few times. The ozone gas used may have a concentration from 100 to 500 g/m³, specifically 400 g/m³. The ozone gas permeates the TiO₂ dielectric layer 150 and oxidizes the surface of the Ru bottom electrode 140a. Accordingly, the RuO₂ pretreated layer 146 can be formed at the surface of the Ru bottom electrode 140a at the same time when the TiO₂ dielectric layer 150 is formed. In this process, the thickness of the RuO₂ pretreated layer 146 may be 5 or less nm. Specifically, when the RuO₂ pretreated layer 146 is formed as described above, an increase in roughness of the Ru bottom electrode 140a can be decreased, and the fabrication process can be simplified.

The method of forming the TiO₂ dielectric layer 150, specifically, the impurity doping can be the same as described with reference to FIGS. 9 and 10 according to the second embodiment. FIG. 12 illustrates a method of doping an impurity on the TiO₂ dielectric layer 150 in the current embodiment in which after the TiO₂ dielectric layer 150 begins to be formed and before the TiO₂ dielectric layer 150 is completely formed, the RuO₂ pretreated layer 146 is formed. The flow chart illustrated in FIG. 12 is similar to the flow chart illustrated in FIG. 10, but the current embodiment can be characterized with use of ozone gas or oxygen plasma as an oxidant.

The current embodiment is characterized in that the process of forming the RuO₂ pretreated layer 146 is not performed separately. That is, the RuO₂ pretreated layer 146 can be formed using ozone gas or oxygen plasma as an oxidant when the TiO₂ dielectric layer 150 is formed. Thus, the fabrication process can be simplified.

The present invention will be described in further detail with reference to the following examples. Some of detailed descriptions will not be described since those of ordinary skill in the art may sufficiently induce technically. These examples are for illustrative purposes only and are not intended to limit the scope of the present invention.

### EXPERIMENTAL EXAMPLE 1

A TiO₂ dielectric layer was formed according to the third embodiment of the present invention in which a RuO₂ pretreated layer is formed when a TiO₂ dielectric layer is formed. However, an impurity was not doped on the TiO₂ dielectric layer. Specifically, a TiO₂ dielectric layer was formed on a Ru bottom electrode using TTIP and ozone gas at 250° C. In this process, traveling wave-type atomic layer deposition (ALD) equipment was used. The TiO₂ dielectric layer was post heat treated at 400° C. and at an N₂ 95% /O₂ 5% atmosphere.

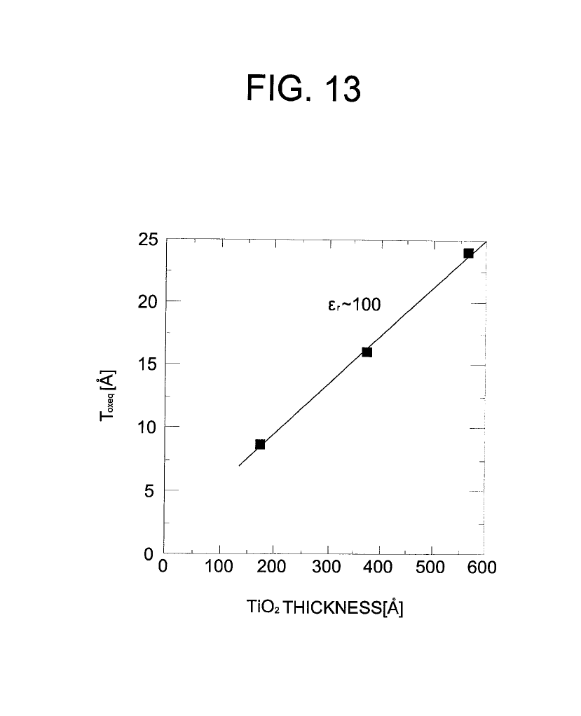

FIG. 13 is a graphical view of an equivalent oxide thickness (T_{oxeq}) with respect to a physical thickness of a TiO₂ dielectric layer on which Al is not doped. From the slope of the graph, it was identified that dielectric constant of the TiO₂ dielectric layer is approximately 100.

As described above, when the TiO₂ dielectric layer has an anatase crystal structure, the TiO₂ dielectric layer shows relative dielectric constant of 30 to 40, whereas when the TiO₂ dielectric layer has a rutile crystal structure, the TiO₂ dielectric layer shows relative dielectric constant of about 90 along an a-axis, but shows relative dielectric constant of about 170 along a c-axis. According to the current experimental example, although the TiO₂ dielectric layer was formed at a temperature as low as 250° C., the TiO₂ dielectric layer had a rutile crystal structure since the dielectric constant of the TiO₂ dielectric layer was about 100. Such result may be due to the fact that the surface of the Ru bottom electrode was oxidized as a result of the oxidation reaction of ozone gas to form a RuO₂ pretreated layer when the TiO₂ dielectric layer is formed. In addition, the TiO₂ dielectric layer had dielectric constant between 90 and 170, and thus, it was found that the rutile crystal structure is randomly arranged.

### EXPERIMENTAL EXAMPLE 2

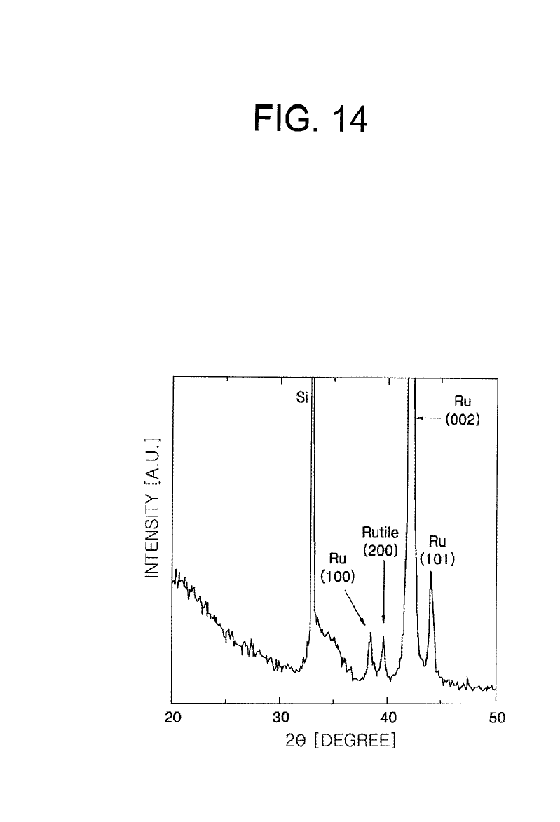

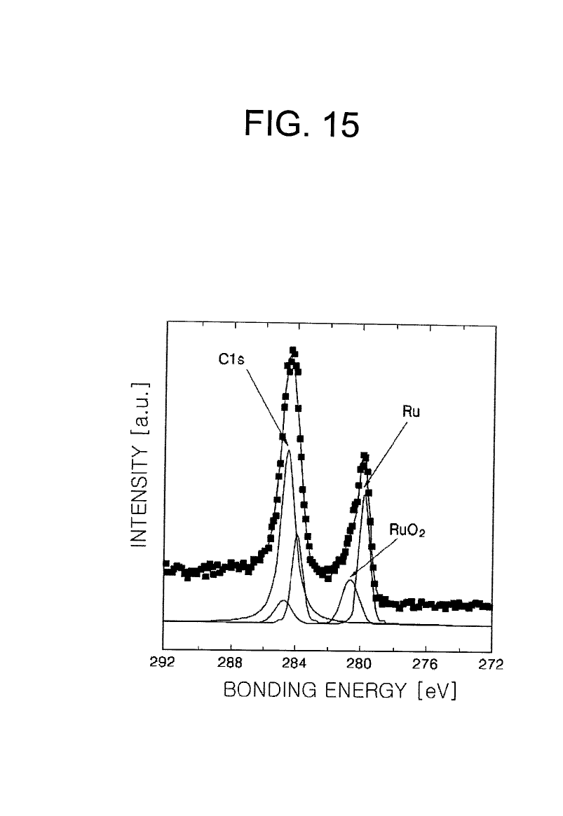

FIG. 14 illustrates results of an X-ray diffraction (XRD) analysis of a TiO₂ dielectric layer formed according to a third embodiment of the present invention, and FIG. 15 illustrates a X-ray photoelectron spectroscopy (XPS) spectra of the interface between a Ru electrode and a TiO₂ dielectric layer when the TiO₂ dielectric layer is formed according to a third embodiment of the present invention. As illustrated in FIG. 14, a TiO₂ dielectric layer which was formed on a Ru electrode using an ALD process using ozone gas shows a rutile crystal structure. Such result may be obtained due to the fact that as illustrate in FIG. 15, when a TiO₂ dielectric layer is formed using an ALD process using ozon gas, the surface of the Ru electrode was changed into a thin RuO₂ layer.

### EXPERIMENTAL EXAMPLE 3

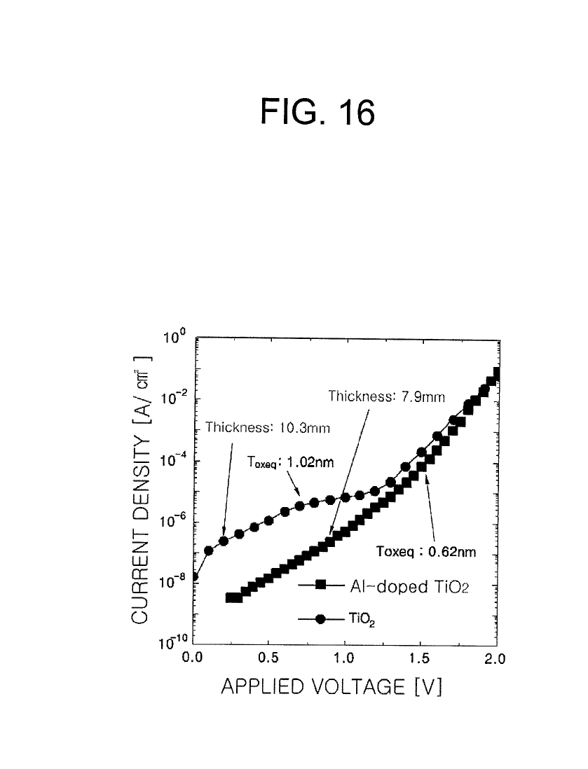

FIG. 16 is a graphical view of a leakage current with respect to voltage (J-V) of an Al-doped TiO₂ dielectric layer and an un-doped TiO₂ dielectric layer. In the current experiment, Pt was deposited using electron beam evaporation method to form a top electrode. In FIG. 16, the graph of the Al-doped TiO₂ dielectric layer is represented by ‘▪’, and the graph of the un-doped TiO₂ dielectric layer is represented by ‘.’ As described above, the doping with an impurity on the dielectric layer according to the present invention decreases leakage current, but also results in a slight decrease in dielectric constant of the TiO₂ dielectric layer. Accordingly, the doping concentration should be determined in consideration of such problems. The inventors of the present application found that when Al is used as an impurity, an appropriate doping concentration is in the range from 1 to 15 at %.

Referring to FIG. 16, it was found that when Al having an appropriate content is doped on the TiO₂ dielectric layer, an equivalent oxide thickness is smaller but the leakage current is much smaller in a range from 0.5-1 V, than when Al was not doped on the TiO₂ dielectric layer. In addition, when Al is doped dielectric constant can also be reduced due to addition of Al, which is not illustrated in the drawing. According to the current experiment, it was found that when Al is not doped on the TiO₂ dielectric layer, dielectric loss was about 2%, but when Al is doped on the TiO₂ dielectric layer, the dielectric loss was substantially decreased to 0.5%.

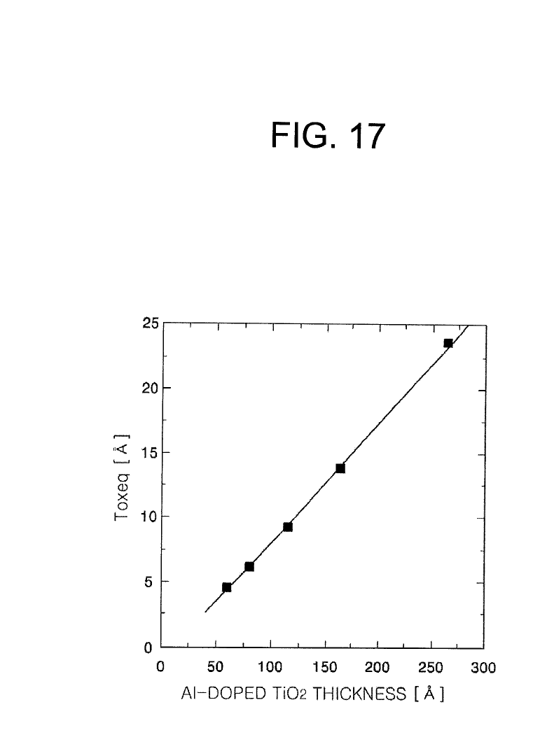

FIG. 17 is a graphical view of an equivalent oxide thickness with respect to a physical thickness of an Al-doped TiO₂ dielectric layer prepared by doping with Al having an optimal doping concentration. From the slope of the graph, it was found that dielectric constant of the dielectric layer is about 50, and obtainable minimum equivalent oxide thickness is about 0.5 nm.

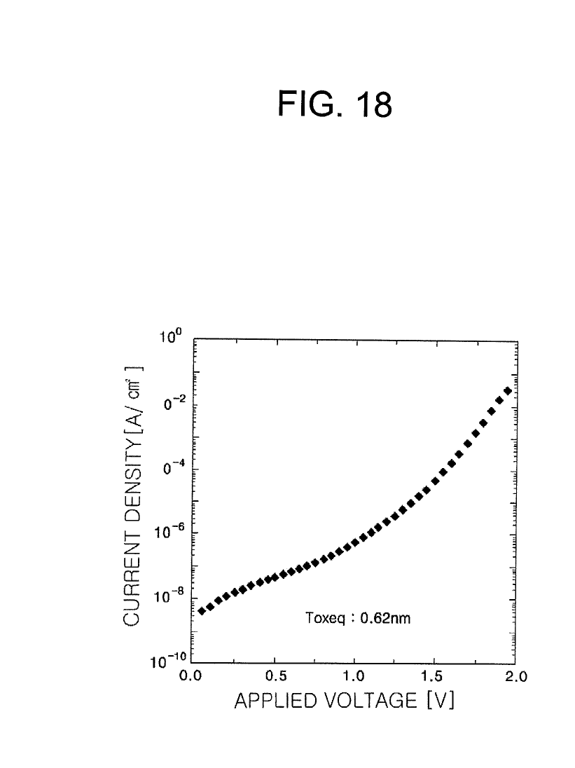

FIG. 18 is a graphical view of a leakage current with respect to voltage (J-V) of an Al-doped TiO₂ dielectric layer prepared by doping with Al having an optimal doping concentration. The graph shows that at an equivalent oxide thickness of about 0.62 nm of an equivalent oxide thickness, the leakage current was maintained to 5×10⁻⁷ A/cm² @ 0.8V or lower, which is required by the DRAM capacitor.

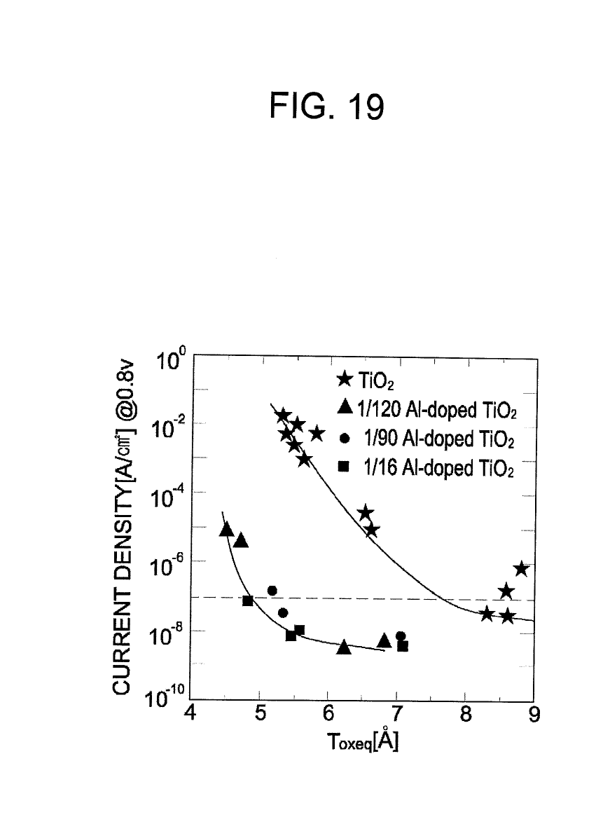

FIG. 19 is a graphical view of a leakage current with respect to an equivalent oxide thickness of an Al-doped TiO₂ dielectric layer and an un-doped TiO₂ dielectric layer. The graph of the un-doped TiO₂ dielectric layer is represented by ‘★’, the graph of the TiO₂ dielectric layer doped with 1/120 Al is represented by ‘▴’, the graph of the TiO₂ dielectric layer doped with 1/90 Al is represented by ‘▪’, and the graph of the TiO₂ dielectric layer doped with 1/60 Al is represented by ‘.’ Here, 1/120, 1/90, 1/60 represent the cycle number ratio of Al₂O₃ and TiO₂ deposition. For example, 1/120 corresponds to the case where the 1 cycle of Al₂O₃ deposition was performed for 120 cycles of TiO₂ deposition. Referring to FIG. 19, at the leakage current of 1×10⁻⁷ A/cm² @ 0.8V or lower, the Al-doped TiO₂ dielectric layer according to the present invention can have an equivalent oxide thickness of 4.8 Å or lower. At an equivalent oxide thickness of about 5-6 Å, the Al-doped TiO₂ dielectric layer can have a leakage current about 10⁵ times smaller than the un-doped TiO₂ dielectric layer.

As illustrated in FIG. 19, data obtained using the Al-doped TiO₂ dielectric layer is arranged in a single line independently from its doping concentration. Thus, it can be seen that within the range illustrated in the graph, it is not that important to accurately adjust the doping concentration of Al to decrease the leakage current. Accordingly, the embodiment of the present invention described above is very suitable for mass production in consideration that a slight variation in the doping concentration of Al does not involve so much variation in the electrical performance of the device in mass production.

Referring to FIGS. 17 through 19, it can be seen that although the Al-doped TiO₂ dielectric layer has lower dielectric constant than the un-doped TiO₂ dielectric layer as illustrated in FIG. 13, the decrease in leakage current overcompensate for the loss of capacitance by the decreased dielectric constant owing to the doping and a much smaller equivalent oxide thickness which are required by a DRAM capacitor can be obtained from the properly doped TiO₂ films. The decreased dielectric constant of the Al-doped TiO₂ film requires further reduction of the physical thickness of the dielectric film in order to achieve the same equivalent oxide thickness. The reduction in the physical thickness may increase the leakage current under the same applied voltage compared to the non-doped TiO₂ film. However, the reduction in leakage current by the Al-doping overwhelms this adverse effect so that the overall dielectric performance was largely improved.

### EXPERIMENTAL EXAMPLE 4

The case that Al is doped as an impurity is compared to the case that Hf is doped as an impurity. The Al doping was performed by supplying an Al-containing impurity source in a vapor phase when a TiO₂ dielectric layer was formed, on the other hand, the Hf doping was performed by depositing a HfO₂ layer on the TiO₂ dielectric layer using an ALD method and then diffused.

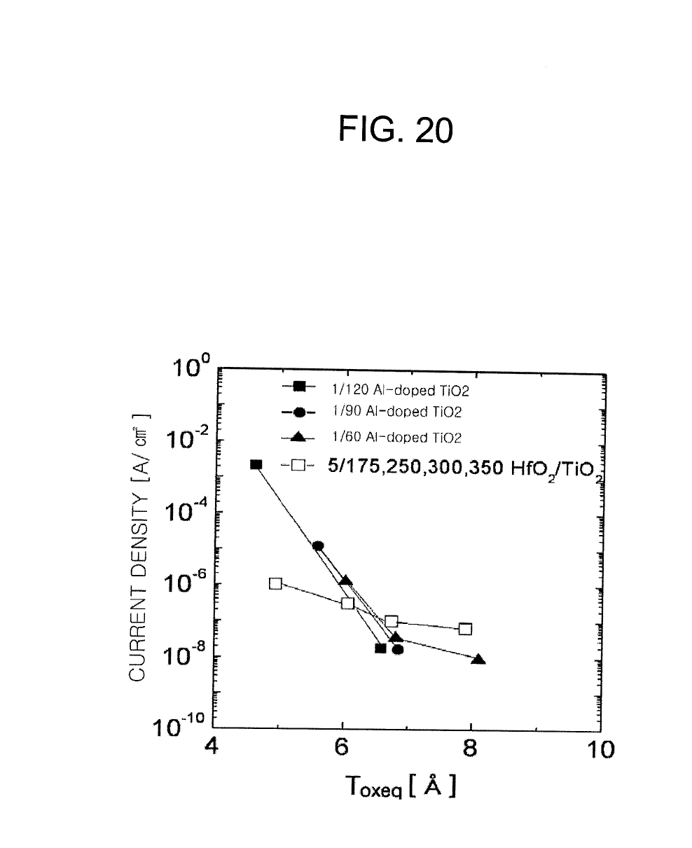

FIG. 20 is a graphical view of a leakage current with respect to an equivalent oxide thickness of an Al-doped TiO₂ dielectric layer and an Hf-doped TiO₂ dielectric layer.

In FIG. 20, the graphs of the Al-doped TiO₂ dielectric layer are represented by ‘▪’, ‘’, and ‘▴,’ on the other hand, the graph of the Hf-doped TiO₂ dielectric layer is represented by ‘□.’ The graph of the Al-doped TiO₂ dielectric layer represented by ‘▪’ was obtained by repeating the TiO₂ deposition cycle 120 times and repeating the Al doping cycle once. The graph of the Al-doped TiO₂ dielectric layer represented by ‘’ was obtained by repeating the TiO₂ deposition cycle 90 times, and repeating the Al doping cycle once. The graph of the Al-doped TiO₂ dielectric layer represented by ‘’ was obtained by repeating the TiO₂ deposition cycle 60 times and repeating the Al doping cycle once. The data represented by ‘□’ were obtained by repeating the TiO₂ deposition cycle 175 times, 250 times, 300 times, and 350 times, and in each case, the HfO₂ deposition cycle was repeated 5 times, which corresponds to the case that a TiO₂ dielectric layer is deposited to a thickness from about 8 to 10 nm and then HfO₂ is deposited thereon to a thickness of about 0.5 nm.

Referring to FIG. 20, it can be found that the leakage current of the Hf-doped TiO₂ dielectric layer was the same as or 5 times lower than the leakage current of the Al-doped TiO₂ dielectric layer, at the same equivalent oxide thickness. Specifically, when the equivalent oxide thickness is 6 Å or less, the Hf-doped TiO₂ dielectric layer had smaller leakage current than the Al-doped TiO₂ dielectric layer.

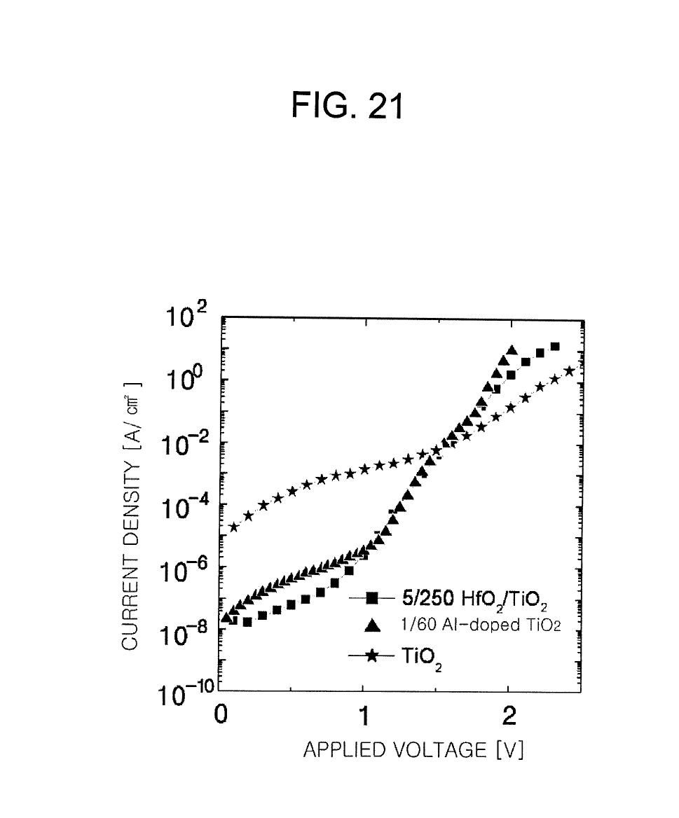

FIG. 21 is a graphical view of a leakage current with respect to voltage (J-V) of an Al-doped TiO₂ dielectric layer, an Hf-doped TiO₂ dielectric layer, and an impurity-undoped TiO₂ dielectric layer, at the same equivalent oxide thickness of 6 Å.

In FIG. 21, the graph of the Hf-doped TiO₂ dielectric layer is represented by ‘▪,’ and was obtained by performing the TiO₂ deposition cycle 250 times and the HfO₂ deposition cycle five times; the graph of the Al-doped TiO₂ dielectric layer is represented by ‘▴,’ and was obtained by performing the TiO₂ deposition cycle 60 times and the Al doping cycle once; and the graph of the undoped TiO₂ dielectric layer was represented by ‘★.’

Referring to FIG. 21, when a voltage of as low as 1 V or lower is applied, the Hf-doped TiO₂ dielectric layer showed the smallest leakage current.

### EXPERIMENTAL EXAMPLE 5

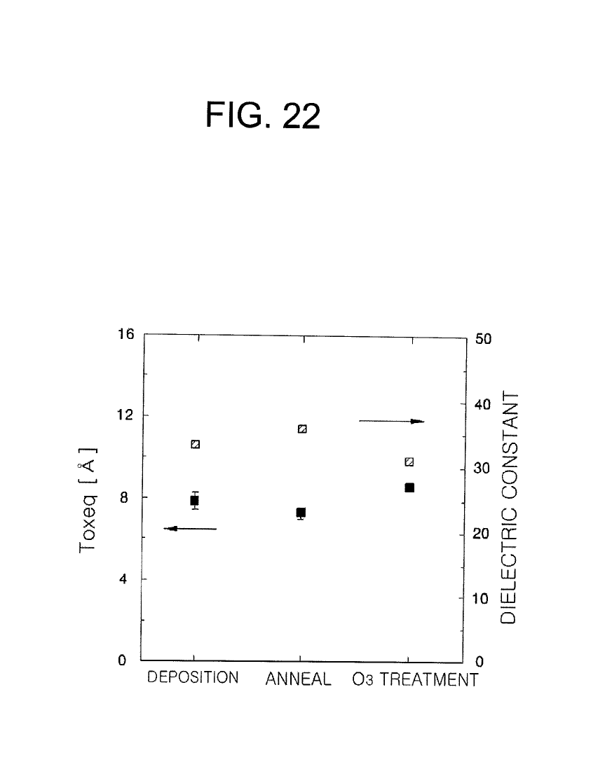

FIG. 22 illustrates the equivalent oxide thickness and dielectric constant of an Al-doped TiO₂ dielectric layer in an as-deposited state, an Al-doped TiO₂ dielectric layer after being subjected to a post heat treatment process, and an Al-doped TiO₂ dielectric layer after being treated with O₃. In FIG. 22, an equivalent oxide thickness is represented by ‘▪,’ and the dielectric constant is represented by [symbol] Referring to FIG. 22, the Al-doped TiO₂ dielectric layer which had been post-thermal treated showed the smallest equivalent oxide thickness and the largest dielectric constant. Accordingly, it can be found that after the dielectric layer is deposited, the post heat treatment should be performed to obtain excellent electrical properties.

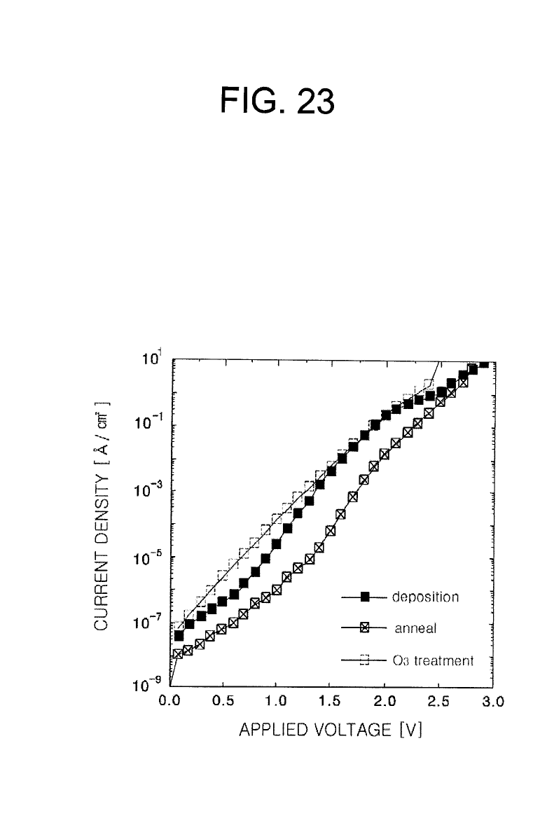

FIG. 23 is a graphical view of a leakage current with respect to voltage (J-V) of an Al-doped TiO₂ dielectric layer in an as-deposited state, an Al-doped TiO₂ dielectric layer after being subjected to a post heat treatment process, and an Al-doped TiO₂ dielectric layer after being treated with O₃. The graph of the Al-doped TiO₂ dielectric layer in an as-deposited state is represented by ‘▪,’ the graph of the Al-doped TiO₂ dielectric layer after being subjected to a post heat treatment process or an annealing process is represented by a symbol ‘square having X therein,’ and the graph of the Al-doped TiO₂ dielectric layer after being treated with O₃ is represented by a symbol ‘square formed in a doted line.’

Referring to FIG. 23, the Al-doped TiO₂ dielectric layer after being subjected to a post heat treatment process showed the smallest leakage current. Accordingly, it can be seen that after the dielectric layer is deposited, the deposited dielectric layer should be subjected to a post heat treatment.

### EXPERIMENTAL EXAMPLE 6

According to the second embodiment of the present invention in which a RuO₂ pretreated layer is formed and then, a TiO₂ dielectric layer is formed, a TiO₂ dielectric layer was formed to prepare a sample according to the present invention. Specifically, a Ru bottom electrode is thermally treated with ozone gas at a temperature of 250° C. for about 15 seconds to form a RuO₂ pretreated layer. Then, a TiO₂ dielectric layer having a thickness of about 27 nm was formed on the RuO₂ pretreated layer using an ALD method, in which a water vapor acted as an oxidant.

To compare with the TiO₂ dielectric layer formed on the RuO₂ pretreated layer which was prepared by pretreating with ozone gas, a TiO₂ dielectric layer was directly formed on a Ru bottom electrode using an ALD method in which a water vapor acted as an oxidant, without pretreatment with ozone gas, to prepare a comparative sample.

Crystal structures of the sample according to the present invention and the comparative sample were identified through an XRD analysis. In this case, however, the XRD analysis cannot be performed since the TiO₂ dielectric layers were too thin and thus there were no peaks of TiO₂. Accordingly, a glancing angle X-ray diffraction (GAXRD) analysis was performed.

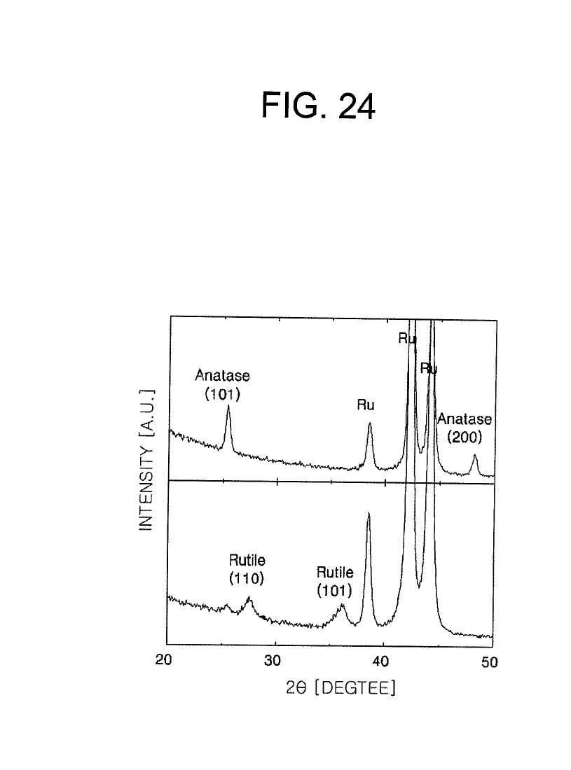

FIG. 24 illustrates results of a glancing angle X-ray diffraction (GAXRD) analysis of a sample prepared according to a second embodiment in which a TiO₂ dielectric layer was formed on a RuO₂ pretreated layer which had been formed by pre-treating with ozone gas and a comparative sample in which a TiO₂ dielectric layer was directly formed on a Ru bottom electrode using an ALD method in which a water vapor acted as an oxidant without a pre-treatment process using an ozone gas. In FIG. 24, the upper spectrum relates to the comparative sample, and the lower spectrum relates to the sample according to the present invention.

The upper spectrum of the comparative sample in which a TiO₂ dielectric layer was directly formed on a Ru bottom electrode using an ALD method in which a water vapor acted as an oxidant without a pre-treatment process using an ozone gas includes 101 and 200 peaks of anatase. The lower spectrum of the sample according to the present invention includes 110 and 101 peaks of rutile.

As a result, it can be found that when the Ru bottom electrode is pre-treated with ozone gas, a TiO₂ dielectric layer having a rutile crystal structure can be formed even using an ATD method in which a water vapor can be used as an oxidant.

### EXPERIMENTAL EXAMPLE 7

Like Experimental Example 6, according to the second embodiment, a TiO₂ dielectric layer was formed on a RuO₂ pretreated layer which had been formed by pre-treating with ozone gas using an ALD method in which a water vapor acted as an oxidant, which is referred to as a sample 1. A TiO₂ dielectric layer was directly formed on a Ru bottom electrode using an ALD method in which a water vapor acted as an oxidant without pre-treating with ozone gas, which is referred to as a comparative sample. According to the third embodiment of the present invention, instead of formation of the RuO₂ pretreated layer first, a RuO₂ pretreated layer was formed when a TiO₂ dielectric layer was formed using an ALD method in which an ozone gas acted as an oxidant. These samples are referred as sample 2.

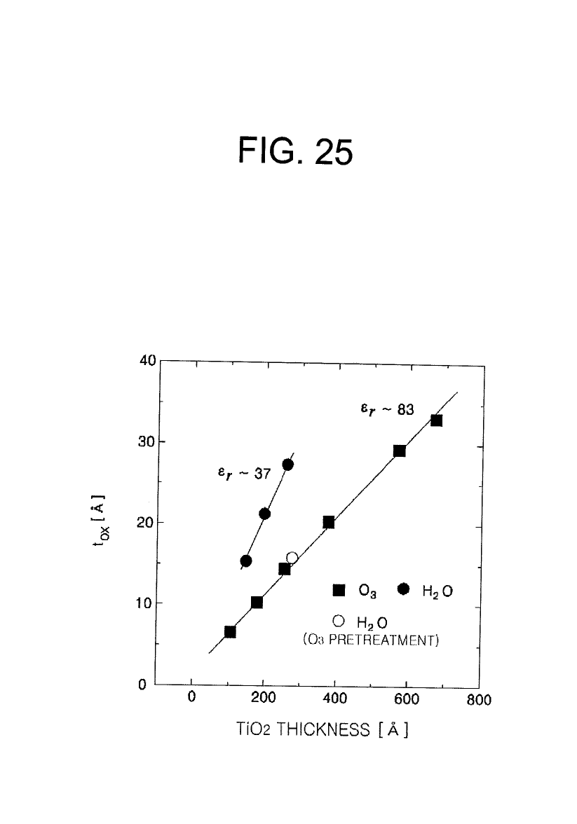

FIG. 25 is a graphical view of an equivalent oxide thickness with respect to a physical thickness of a TiO₂ dielectric layer formed according to respective methods described above. In FIG. 25, the graph of the sample 1 is represented by ‘◯,’ the graph of the comparative sample is represented by ‘,’ and the graph of the sample 2 is represented by ‘▪.’

Referring to FIG. 25, the sample 1 and the sample 2 showed dielectric constant of about 83, and the comparative sample showed the dielectric constant of about 37. Accordingly, it can be found that the TiO₂ dielectric layers prepared according to the second and third embodiments can have the rutile crystal structure.

### EXPERIMENTAL EXAMPLE 8

As described with reference to previous embodiments, a capacitor of a semiconductor device according to the present invention can have a three-dimension bottom electrode structure, such as a cylinder-like structure, a concave-like structure, or a stack-like structure. A dielectric layer formed on the three-dimension bottom electrode can also have a three-dimension structure, and in general, a layer formed on upper, side, and bottom surfaces of the three-dimension structure may have non-uniform thickness, non-uniform crystal structure, and non-uniform electrical properties, according to a deposition method. When the formed layer has non-uniform thickness, properties of the layer can be affected. However, according to a method according to the present invention, the thickness of a TiO₂ dielectric layer formed on a three-dimension structure can be uniform, which is identified in the current Experimental Example.

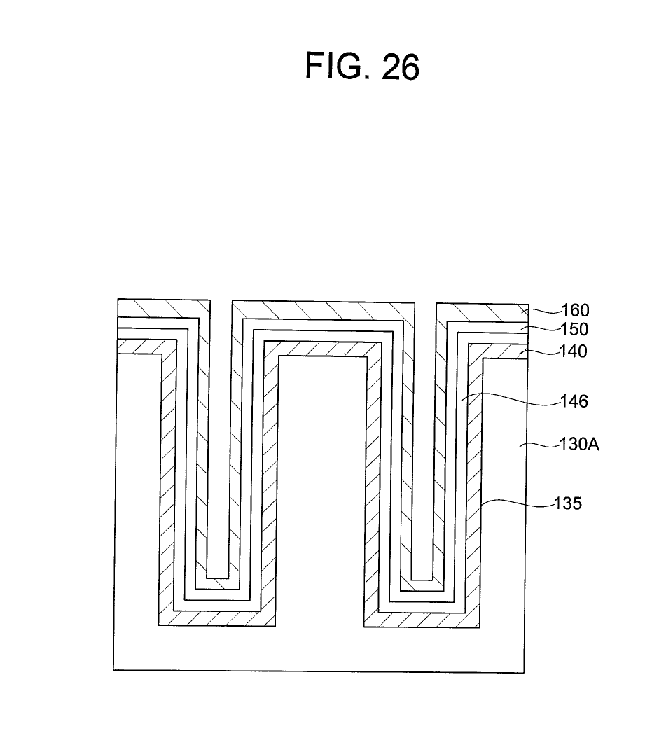

FIG. 26 is a schematic sectional view of a sample used in the current experimental example.

As described in previous embodiments, a mold oxide layer was etched to form a hole 135, and then a Ru layer 140, a RuO₂ pretreated layer 146, a TiO₂ dielectric layer 150, and a top electrode 160 were sequentially formed corresponding to a step of the hole 135 and the mold oxide layer pattern 130a. Respective layers were formed as described in previous embodiments. For comparison, in some samples, a TiO₂ dielectric layer 150 was not doped with an impurity, on the other hand, in other samples, a TiO₂ dielectric layer 150 was doped with Al. To easily illustrate the drawing, the hole 135 was illustrated to have a straight side line. However, when the hole 135 is formed using a Bosch method, the side surface of the hole 135 can have a rumple-like shape.

It is difficult to separately measure dielectric properties of a TiO₂ dielectric layer 150 formed on an upper surface of the hole 135, specifically, an upper surface of a mold oxide layer pattern 130a, and on side and bottom surfaces of the hole 135. So, according to the current embodiment, the size of the hole 135 and the distance between adjacent holes 135 were varied to prepare various samples, and expected capacitances and measured capacitances according to the array geometry of the hole 135 were compared with each other. The expected capacitance was measured using the entire surface area of the hole 135 measured according to the array geometry of the hole 135 after the thickness and dielectric constant of a portion of the TiO₂ dielectric layer 150 formed on the upper surface of the mold oxide layer pattern 130a were measured, while assuming that portions of the TiO₂ dielectric layer 150 formed on the side and bottom surfaces of the hole 135 have the same thickness and dielectric constant as those of the portion of the TiO₂ dielectric layer 150 formed on the upper surface of the mold oxide layer pattern 130a.

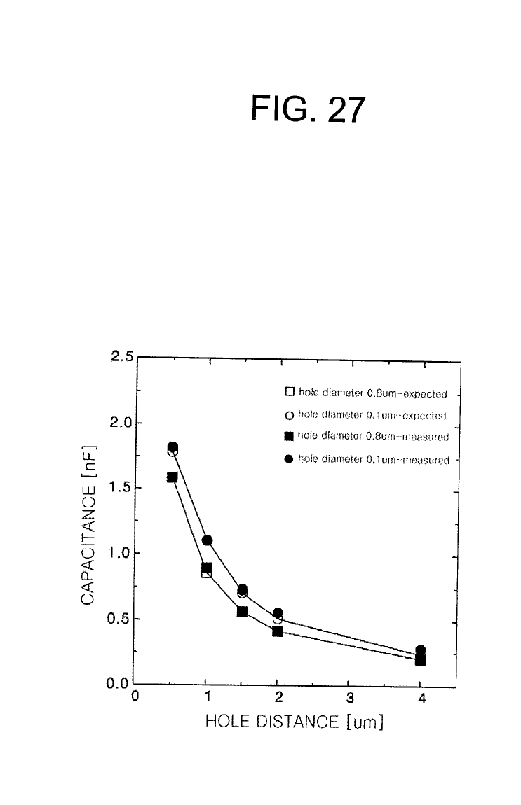

FIG. 27 is a graphical view of capacitance according to the distance between adjacent holes in which an un-doped TiO₂ dielectric layer is deposited, at various hole sizes.

A sample having a hole 135 having an diameter of 0.8 μm and a depth of 4.6 μm and a sample having a hole 135 having a diameter of 1.0 μm and a depth of 6.2 μm were prepared. A distance between adjacent holes 135 was changed from 0.5 μm to 4 μm. The holes are located in an area of 100×100 μm² and undopted TiO₂ capacitor structure is formed. In order to make an electrical contact, a contact pad having the same area is attached to the hole array area.

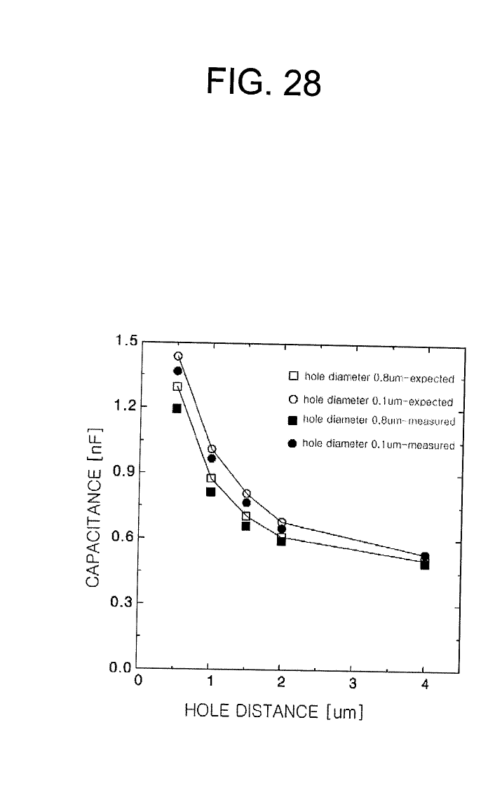

FIG. 28 is a graphical view of capacitance according to the distance between adjacent holes in which an Al-doped TiO₂ dielectric layer is deposited, at various hole sizes.

A sample having a hole 135 having an diameter of 0.8 μm and a depth of 7.5 μm and a sample having a hole 135 having a diameter of 1.0 μm and a depth of 8.3 μm were prepared. A distance between adjacent holes 135 was changed from 0.5 μm to 4 μm. The holes are located in an area of 50×50 μm² and Al-dopted TiO₂ capacitor structure is formed. In order to make an electrical contact, a contact pad having the same area is attached to the hole array area.

Referring to FIGS. 27 and 28, the graphs obtained when the size of the hole is 0.8 μm is represented by ‘▪’ and ‘□’, and the graph obtained when the size of the hole is 1.0 μm is represented by ‘’ and ‘◯’. The graphs of an expected capacitance according to the geometry of the hole array is represented by ‘□’ and ‘◯’, and the graphs of a measured capacitance according to the geometry of the hole array is represented by ‘▪’ and ‘’.

Referring to FIGS. 27 and 28, even when the size of a hole is changed, independently from the doping with Al, the expected capacitances and the measured capacitances were almost the same each other. Since the expected capacitance was obtained on the assumption that the thickness and dielectric properties of the TiO₂ dielectric layer are maintained constant in any location, such a result that the expected capacitances and the measured capacitances were almost the same each other shows that a TiO₂ dielectric layer formed according to the present invention can have upper, side, and bottom surfaces of the three-dimension structure which have a uniform thickness and dielectric properties. Accordingly, a capacitor of a semiconductor device according to the present invention and a method of fabricating the capacitor according to the present invention can be suitable for 50 nm DRAMs which require a dielectric layer having a uniform thickness and a storage capacity of a few giga or more.

The present invention uses a TiO₂ dielectric layer having a simpler structure than a three-component dielectrics, such as (Ba, Sr) TiO₃, having a perovskite structure, which is difficult to be fabricated. Thus, in a ULSI-DRAM process for fabricating a semiconductor device having a giga-level storage capacity, problems arising when a capacitor is fabricated can be substantially overcome.

When a TiO₂ dielectric layer is formed on a RuO₂ pretreated layer to have a rutile crystal structure according to the present invention, a dielectric layer having high dielectric constant can be formed even at low temperature. In addition, since an impurity is doped on the TiO₂ dielectric layer to decrease leakage current, a dielectric layer can have an equivalent oxide thickness of 0.5 nm or less. Furthermore, in all the process described above can be performed at 400° C. or less when a layer is deposited, and at 500° C. or less even when a post heat treatment is performed after the deposition. Thus, deterioration of a Ru electrode, that is, deformation of a Ru electrode due to heat can be prevented.

Accordingly, a capacitor of a semiconductor device according to the present invention and a method of fabricating the capacitor according to the present invention are suitable for 50 nm DRAMs.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A capacitor of a semiconductor device, the capacitor comprising:
a Ru bottom electrode formed on a semiconductor substrate;
a rutile-structured RuO₂ pretreated layer which is formed by oxidizing the Ru bottom electrode;
a TiO₂ dielectric layer which has a rutile crystal structure corresponding to the rutile crystal structure of the RuO₂ pretreated layer and is doped with an impurity; and
a top electrode formed on the TiO₂ dielectric layer.

2. The capacitor of claim 1, wherein the thickness of the RuO₂ pretreated layer is 5 nm or less.

3. The capacitor of claim 1, wherein the impurity comprises at least one substance selected from Al and Hf, and the concentration of the impurity is in the range from 0.1 at % to 20 at %.

4. The capacitor of claim 3, wherein the top electrode is formed of a novel metal, heat-resistance metal, heat-resistance metal nitrate, or conductive oxide.

5. The capacitor of claim 1, wherein the bottom electrode can also be deposited RuO₂ by the atomic layer deposition (ALD) with or without plasma or chemical vapor deposition (CVD).

6. A method of fabricating a capacitor of a semiconductor device, the method comprising:
forming a Ru bottom electrode on a semiconductor substrate;
forming a rutile-structured RuO₂ pretreated layer by oxidizing a surface of the Ru bottom electrode;
forming a TiO₂ dielectric layer to have a rutile crystal structure corresponding to the rutile crystal structure of the RuO₂ pretreated layer on the a RuO₂ pretreated layer, and doping the TiO₂ dielectric layer with an impurity; and
forming a top electrode on the TiO₂ dielectric layer.

7. The method of claim 6, wherein the thickness of the RuO₂ pretreated layer is 5 nm or less.

8. The method of claim 6, wherein the impurity comprises at least one substance selected from Al and Hf, and the concentration of the impurity is in the range from 0.1 at % to 20 at %.

9. The method of claim 8, wherein the top electrode is a novel metal, heat-resistance metal, heat-resistance metal nitrate, or conductive oxide.

10. The capacitor of claim 6, wherein the bottom electrode can also be deposited RuO₂ by the atomic layer deposition (ALD) with or without plasma or chemical vapor deposition (CVD).

11. The method of claim 6, wherein the RuO₂ pretreated layer is formed and then the TiO₂ dielectric layer begins to be formed, or the RuO₂ pretreated layer is formed in the process of forming the TiO₂ dielectric layer.

12. The method of claim 6, wherein the Ru bottom electrode is formed through atomic layer deposition (ALD) with or without plasma or chemical vapor deposition (CVD).

13. The method of claim 6, wherein the RuO₂ pretreated layer is formed by performing a heat treatment on the Ru bottom electrode using an ozone gas or oxygen plasma before the TiO₂ dielectric layer begins to be formed.

14. The method of claim 6, wherein the RuO₂ pretreated layer is formed using an ozone gas or oxygen plasma acting as an oxidant when the TiO₂ dielectric layer is formed.

15. The method of claim 6, wherein the process for forming the RuO₂ pretreated layer and the process for forming the TiO₂ dielectric layer are performed in-situ, wherein
the semiconductor substrate is loaded to a reaction chamber;
an ozone gas or oxygen plasma is supplied to the reaction chamber to oxidize the surface of the Ru bottom electrode so as to form the RuO₂ pretreated layer; and
the TiO₂ dielectric layer is formed using an atomic layer deposition method that a TiO₂ deposition cycle is repeated several times, wherein
the TiO₂ deposition cycle comprises:
supplying a Ti precursor to the reaction chamber,
purging the Ti precursor out of the reaction chamber,
supplying an oxidant to the reaction chamber, and
purging the oxidant out of the reaction chamber.

16. The method of claim 15, wherein the oxidant is ozone gas, water vapor, or oxygen plasma.

17. The method of claim 6, the process for forming the RuO₂ pretreated layer and the process for forming the TiO₂ dielectric layer are performed in-situ, wherein
the semiconductor substrate is loaded to a reaction chamber; and
the TiO₂ dielectric layer is formed using an atomic layer deposition method that a TiO₂ deposition cycle is repeated several times, and at the same time, the surface of the Ru bottom electrode is oxidized using the ozone gas or oxygen plasma so as to form the RuO₂ pretreated layer, wherein
the TiO₂ deposition cycle comprises:
supplying a Ti precursor to the reaction chamber,
purging the Ti precursor out of the reaction chamber,
supplying an oxidant to the reaction chamber, and
purging the oxidant out of the reaction chamber.

18. The method of claim 15, the impurity comprises at least one substance selected from Al and Hf, and the concentration of the impurity is in the range from 0.1 at % to 20 at %,
wherein to dope with the at least one substance selected from Al and Hf, an impurity source comprising the at least one substance selected from Al and Hf is supplied in a vapor phase when the TiO₂ dielectric layer is formed.

19. The method of claim 15, the impurity comprises at least one substance selected from Al and Hf, and the concentration of the impurity is in the range from 0.1 at % to 20 at %,
wherein to dope with the at least one substance selected from Al and Hf, a cycle comprising a TiO₂ deposition cycle and a doping cycle is performed several times, wherein
the TiO₂ deposition cycle is repeated n times where n≧1 which comprises:
supplying a Ti precursor to the reaction chamber,
purging the Ti precursor out of the reaction chamber,
supplying an oxidant to the reaction chamber, and
purging the oxidant out of the reaction chamber
the doping cycle, which is performed after the TiO₂ deposition cycle, comprises:
supplying an impurity source comprising the at least one substance selected from Al and Hf to the reaction chamber, and
purging the impurity source out of the reaction chamber.

20. The method of claim 15, the impurity comprises at least one substance selected from Al and Hf, and the concentration of the impurity is in the range from 0.1 at % to 20 at %,
wherein to dope with the at least one substance selected from Al and Hf, an impurity source layer comprising the at least one substance selected from Al and Hf is deposited on the TiO₂ dielectric layer, and then the at least one substance selected from Al and Hf is diffused to the TiO₂ dielectric layer.
